(19) United States
(12) Patent Application Publication
(10) Pub. No.: US 2016/0351286 A1
(43) Pub. Date: Dec. 1, 2016

(54) COMPOSITION AND METHOD FOR MAKING PICOCRYSTALLINE ARTIFICIAL CARBON ATOMS

(71) Applicant: SemiNuclear, Inc., Plano, TX (US)

(72) Inventor: Patrick Curran, Plano, TX (US)

(21) Appl. No.: 15/167,672

(22) Filed: May 27, 2016

Related U.S. Application Data
(60) Provisional application No. 62/167,418, filed on May 28, 2015.

(51) Int. Cl. H01B 1/06; C23C 16/46

(52) U.S. Cl. CPC H01B 1/06; C23C 16/46

(57) ABSTRACT

Materials containing picocrystalline quantum dots that form artificial atoms are disclosed. The picocrystalline quantum dots (in the form of boron icosahedra with a nearly-symmetrical nuclear configuration) can replace corner silicon atoms in a structure that demonstrates both short range and long-range order as determined by x-ray diffraction of actual samples. A novel class of boron rich compositions that self-assemble from boron, silicon, hydrogen and, optionally, oxygen is also disclosed. The preferred stoichiometric range for the compositions is (B₁₂H_{w})ₓSi_{y}O_{z} with 3≦w≦5, 2≦x≦3, 2≦y≦5 and 0<z≦3. By varying oxygen content and the presence or absence of a significant impurity such as gold, unique electrical devices can be constructed that improve upon and are compatible with current semiconductor technology.

### CLAIM OF PRIORITY

This application claims priority to U.S. Provisional Application No. 62/167,418, entitled “Self-Assembled Supramolecular Oxysilaborane and Method for Making Same,” filed on May 28, 2015; the disclosure of which is hereby incorporated by reference.

### FIELD OF THE INVENTION

This invention relates to a boron-rich composition of matter and, more particularly, to a self-assembled solid picocrystalline oxysilaborane composition of matter. It further pertains to a method of making such composition.

### BACKGROUND OF THE INVENTION

As discussed by Becker et al., in a paper “Boron, The New Graphene?” in Vacuum Technology & Coating, April 2015, pp. 38-44, boron supports a unique and mysterious chemistry that has greatly perplexed scientists for many years in the pursuit of useful commercial applications that continue to defy a full chemical understanding. As further discussed in this article, there is an increasing belief by many scientists that new boron compounds could possibly exist in allotropes or polymorphs similar to, and superior to, the recently discovered carbon allotropes comprising fullerenes, carbon nanotubes, and graphene.

Boron is a light electron-deficient element with a small interatomic spacing between boron atoms so as to support a shared molecular bonding orbital and two shared molecular antibonding orbitals amongst three boron atoms. As the result of this property boron atoms tend to form three-center chemical bonds such that two valence electrons bond three boron atoms, with the peak electron density in the center of the triangle comprised by three boron atoms. This type of chemical bond is very different from a two-center chemical bond in which the peak electron density exists along the rectilinear axis joining two valence electrons. Although boron is a Group-III element, it does not chemically behave like all other Group-III elements. Boron acts like a nonmetal and forms an extended series of hydrides.

Due to three-center bonds, boron tends to form polyhedral molecules comprising triangular faces. The highest-order symmetrical polyhedron formed by triangular faces is an icosahedron with twenty equilateral triangular faces which are interconnected by thirty edges so as to result in twelve vertices. Each vertex of a boron icosahedron is occupied by a boron atom with three valence electrons, such that conventional two-center chemical bonds cannot exist along the 30 icosahedral edges. In a boron icosahedron the coordination number is greater than the number of boron valence electrons, so as to thus necessitate an electron deficiency. Similar to buckminsterfullerene C60, boron icosahedra can form a cage-like molecule, but, as noted below, boron icosahedra formed by only triangular faces display a higher symmetry than the truncated icosahedral buckminsterfullerene molecule formed by 20 regular hexagonal faces and 12 regular pentagonal faces.

In a landmark paper, “The Electronic Structure of an Icosahedron of Boron,” Proceedings of the Royal Society, A230, 1955, p. 110, Longuet-Higgins and Roberts developed the molecular bonding conditions of a closed-shell boron icosahedron that exhibits a full icosahedral symmetry Iₕ with a boron nucleus at each vertex. Longuet-Higgins and Roberts obtained the 48 molecular orbitals of a boron icosahedron by a linear combination of 48 nonorthogonal atomic orbitals that were related to 48 symmetry orbitals in terms of the irreducible representations of the icosahedral group Iₕ comprising the nondegenerate (A_{g}) irreducible representation along with threefold (T₁ᵤ, T_{1g}, T₂ᵤ, T_{2g}), fourfold (Gᵤ, G_{g}), and fivefold (Hᵤ, H_{g}) degenerate irreducible representations of a regular icosahedron.

As developed by Jahn and Teller in “Stability of Polyatomic Molecules in Degenerate Electronic States. I. Orbital Degeneracy,” Proceedings of the Royal Society A, Vol. 161, 1937, pp. 220-235: All nonlinear nuclear configurations are unsuitable for an orbitally-degenerate electronic state. It is very significant that the orbital degeneracy considered by Jahn and Teller explicitly excluded a degeneracy due to spin. The bonding and antibonding orbitals of icosahedral boron manifestly involve nonlinear orbitally-degenerate electronic states. The Jahn-Teller effect results in a symmetry-breaking which lifts electronic orbital degeneracies by normal displacements of the 12 nuclei, known as Jahn-Teller-active modes, which distort polyatomic ions and molecules. The vibrational Jahn-Teller-active modes can be described in terms of the same irreducible representations as the electronic state, such that the vibronic state is specified in terms of irreducible representations.

In the known boron-rich solids, the icosahedral symmetry is broken and the boron icosahedra are distorted by the Jahn-Teller effect. Most boron-rich solids in the prior art act as inverted molecular solids in which intericosahedral bonds are stronger than the intraicosahedral bonds. Icosahedral boron-rich solids are often referred to as inverted molecules. What is needed in the art is a genus of icosahedral boron-rich solids in which an icosahedral symmetry is preserved. Such materials potentially offer electronic properties that are at least as important as those found in graphene, with the additional capability of being compatible with monocrystalline silicon using standard manufacturing techniques. An excellent survey of boron-rich solids is given by Emin in “Unusual properties of icosahedral boron-rich solids,” Journal of Solid-State Chemistry, Vol. 179, 2006, pp. 2791-2798.

There potentially exists a novel form of boron capable of overcoming limitations of recently discovered allotropes of carbon comprising the fullerenes, carbon nanotubes, and graphene. While the study of graphene has advanced the general understanding of quantum electrodynamics in condensed matter physics, inherent limitations in its structure and, indeed, the structure of the allotropes of carbon, hinder practical applications. Chief among such limitations is an inability to combine these materials with monocrystalline silicon, on which the electronics industry has been built. Boron, which sits adjacent to carbon on the periodic chart, provides an alternative bridge between quantum electrodynamics and condensed matter physics, with the singular added benefit that, by carefully controlling its form, it can be integrated with silicon in a novel picocrystalline polymorph.

### SUMMARY OF THE INVENTION

A novel class of boron rich compositions that self-assemble from boron, silicon, hydrogen and, optionally, oxygen is disclosed. Self-assembly will occur with or without oxygen and oxygen content can be varied as required. An impurity that alters electrical properties, hereinafter referred to as a “significant impurity” such as gold, for example, can optionally be included in minor amounts. The compositions can be formed by vapor deposition on a substrate. Monocrystalline silicon can be employed as the substrate. This novel class of self-assembled boron compounds exhibit unique electrical properties.

In accordance with the present invention, the compositions have the formula: (B12Hw)xSiyOz, where boron content is greater than about 50% by atomic weight. These novel solid compositions of matter are hereinafter referred to as “oxysilaborane”. Some species of the compositions do not contain oxygen (z=0) and such species may sometimes be referred to as “silaborane.” The preferred stoichiometric range for the compositions is (B12Hw)xSiyOz with 3≦w≦5, 2≦x≦3, 2≦y≦5 and 0<z≦3. Boron is preferably present in from about 63% to about 89% by atomic weight. A particularly preferred composition is where w=4, x=2, y=4 and z=2. These compositions can also include trace amounts of significant impurities that do not affect the atomic ratios set forth above. A preferred significant impurity would be a coinage metal such as gold. The oxygen content of the compositions can be varied so as to form regions of higher or lower oxygen content in the oxysilaborane by, for example, controlling the rate of delivery of oxygen containing gases to the reaction site. In like fashion, should it be desirable to employ gold or another significant impurity in trace amounts to alter electrical properties, a metal containing compound can be introduced to the reaction site for deposition along with the self-assembled oxysilaborane. Such trace additions of a significant impurity do not affect the basic stoichiometry of the compositions.

These materials are also unique in that they contain picocrystalline quantum dots that form artificial atoms. The picocrystalline quantum dots (in the form of boron icosahedra with a nearly-symmetrical nuclear configuration) can replace corner silicon atoms in a structure that demonstrates both short range and long-range order as determined by x-ray diffraction of actual samples. The picocrystalline oxysilaboranes tend to form a borane solid with a continuous network quite similar to that of monocrystalline silicon, albeit a continuous random network in which certain silicon atoms are selectively replaced by picocrystalline quantum dots comprising boron icosahedra with symmetrical nuclear configuration. By varying oxygen content and the presence or absence of a significant impurity such as gold, unique electrical devices can be constructed that improve upon and are compatible with current semiconductor technology.

### BRIEF DESCRIPTION OF THE DRAWING

Preferred embodiments of the invention are illustrated in the accompanying drawings in which:

FIG. 1 is a micrograph obtained by high-resolution transmission microscopy (HRTEM) of a picocrystalline borane solid deposited on a monocrystalline substrate;

FIG. 2 is an HRTEM fast Fourier transform (FFT) image of the monocrystalline silicon substrate;

FIG. 3 is an FFT image of the picocrystalline borane solid;

FIG. 4 is a graph in terms of interplanar lattice d-spacings of the HRTEM diffraction I intensity of the monocrystalline silicon;

FIG. 5 is a graph in terms of interplanar lattice d-spacings of the HRTEM diffraction intensity of the picocrystalline borane solid;

FIG. 6 is a conventional ω-2θx-ray diffraction (XRD) pattern of a thin picocrystalline borane solid;

FIG. 7 is a GIXRD scan of the same pico-crystalline borane solid scanned in FIG. 6;

FIG. 8 is a second GIXRD scan of the same pico-crystalline borane solid scanned in FIG. 6;

FIG. 9 is an illustration of a boron icosahedron with a symmetrical nuclear configuration shown with four hydrogens bonded by a Debye force;

FIG. 10 is an illustration of a monocrystalline silicon unit cell;

FIG. 11 is an illustration of a diamond-like picocrystalline unit cell

FIG. 12 is an illustration of a silaboride film deposited over a donor-doped region;

FIG. 13 is a graph of a GIXRD scan of the picocrystalline silaboride solid of Example 1;

FIG. 14 is an illustration of an oxysilaborane film deposited over a donor-doped region in accordance with Example 2.

FIG. 15 is a graph of a conventional ω-2θ XRD scan of the thin oxysilaborane solid of Example 2;

FIG. 16 is a graph of a GIXRD scan of the thin oxysilaborane solid of Example 2;

FIG. 17 is an illustration of a silaborane film deposited on a n-type silicon substrate in accordance with Example 3;

FIG. 18 is an x-ray photoelectron spectroscopy (XPS) depth profile of the silaborane film as deposited in Example 3;

FIG. 19 is an Auger electron spectroscopy (AES) depth profile of the silaborane film as deposited in Example 3;

FIG. 20 is an illustration of a silaborane film deposited on a p-type silicon substrate in accordance with Example 4;

FIG. 21 is an x-ray photoelectron spectroscopy (XPS) depth profile of the silaborane film as deposited in Example 4;

FIG. 22 is a linear graph of the current-voltage characteristics of the silaborane film deposited in accordance with Example 4, as measured by an HP-4145 parameter analyzer with the sweep signals obtained by a mercury probe;

FIG. 23 is a log-log graph of the current-voltage characteristics of the silaborane film deposited as in accordance with Example 4, as measured by an HP-4145 parameter analyzer with the sweep signals obtained by a mercury probe;

FIG. 24 is an illustration of an oxysilaborane film deposited on a p-type silicon substrate in accordance with Example 5;

FIG. 25 is an x-ray photoelectron spectroscopy (XPS) depth profile of the oxysilaborane film as deposited in Example 5;

FIG. 26 is a linear graph of the current-voltage characteristics of the oxysilaborane film deposited as in Example 5, as measured by an HP-4145 parameter analyzer with the sweep signals obtained by a mercury probe;

FIG. 27 is a log-log graph of the current-voltage characteristics of the oxysilaborane film deposited as in Example 5, as measured by an HP-4145 parameter analyzer with the sweep signals obtained by a mercury probe;

FIG. 28 is an x-ray photoelectron spectroscopy (XPS) depth profile of the oxysilaborane film as deposited in Example 6;

FIG. 29 is a linear graph of the current-voltage characteristics of the oxysilaborane film deposited as in Example 6, as measured by an HP-4145 parameter analyzer with the sweep signals obtained by a mercury probe;

FIG. 30 is a log-log graph of the current-voltage characteristics of the oxysilaborane film deposited as in Example 6, as measured by an HP-4145 parameter analyzer with the sweep signals obtained by a mercury probe;

FIG. 31 is an x-ray photoelectron spectroscopy (XPS) depth profile of the oxysilaborane film as deposited in Example 7;

FIG. 32 is a linear graph of the current-voltage characteristics of the oxysilaborane film deposited as in Example 7, as measured by an HP-4145 parameter analyzer with the sweep signals obtained by a mercury probe;

FIG. 33 is a log-log graph of the current-voltage characteristics of the oxysilaborane film deposited as in Example 7, as measured by an HP-4145 parameter analyzer with the sweep signals obtained by a mercury probe;

FIG. 34 is an x-ray photoelectron spectroscopy (XPS) depth profile of the oxysilaborane film as deposited in Example 8;

FIG. 35 is a linear graph of the current-voltage characteristics of the oxysilaborane film deposited as in Example 8, as measured by an HP-4145 parameter analyzer with the sweep signals obtained by a mercury probe;

FIG. 36 is a log-log graph of the current-voltage characteristics of the oxysilaborane film deposited as in Example 8, as measured by an HP-4145 parameter analyzer with the sweep signals obtained by a mercury probe;

FIG. 37 is an x-ray photoelectron spectroscopy (XPS) depth profile of the oxysilaborane film as deposited in Example 9;

FIG. 38 is a linear graph of the current-voltage characteristics of the oxysilaborane film deposited as in Example 9, as measured by an HP-4145 parameter analyzer with the sweep signals obtained by a mercury probe;

FIG. 39 is a log-log graph of the current-voltage characteristics of the oxysilaborane film deposited as in Example 9, as measured by an HP-4145 parameter analyzer with the sweep signals obtained by a mercury probe;

FIG. 40 is an illustration of a p-isotype electrochemical rectifier comprising an oxysilaborane film produced in accordance with Example 10;

FIG. 41 is a linear graph of the current-voltage characteristics of the electrochemical rectifier of Example 10, as measured by an HP-4145 parameter analyzer with the sweep signals obtained from the anode and cathode electrodes by means of microprobes;

FIG. 42 is a linear graph of a different current-voltage range of the electrochemical rectifier of Example 10, as measured by an HP-4145 parameter analyzer with the sweep signals obtained from the anode and cathode electrodes by means of microprobes;

FIG. 43 is a log-log graph of the current-voltage characteristics of the electrochemical rectifier of Example 10, as measured by an HP-4145 parameter analyzer with the sweep signals obtained from the anode and cathode electrodes by means of microprobes;

FIG. 44 is a log-log graph of the range depicted in FIG. 42 of current-voltage characteristics of the electrochemical rectifier of Example 10, as measured by an HP-4145 parameter analyzer with the sweep signals obtained from the anode and cathode electrodes by means of microprobes;

FIG. 45 is a linear graph of the current-voltage characteristics of the electrochemical rectifier of Example 11, as measured by an HP-4145 parameter analyzer with the sweep signals obtained from the anode and cathode electrodes by means of microprobes;

FIG. 46 is a linear graph of a different current-voltage range of the electrochemical rectifier of Example 11, as measured by an HP-4145 parameter analyzer with the sweep signals obtained from the anode and cathode electrodes by means of microprobes;

FIG. 47 is a log-log graph of the current-voltage characteristics of the electrochemical rectifier of Example 11, as measured by an HP-4145 parameter analyzer with the sweep signals obtained from the anode and cathode electrodes by means of microprobes;

FIG. 48 is a log-log graph of the range depicted in FIG. 46 of current-voltage characteristics of the electrochemical rectifier of Example 11, as measured by an HP-4145 parameter analyzer with the sweep signals obtained from the anode and cathode electrodes by means of microprobes

FIG. 49 is a linear graph of a first current-voltage range of the electrochemical rectifier of Example 12, as measured by an HP-4145 parameter analyzer with the sweep signals obtained from the anode and cathode electrodes by means of microprobes;

FIG. 50 is a linear graph of a second current-voltage range of the electrochemical rectifier of Example 12, as measured by an HP-4145 parameter analyzer with the sweep signals obtained from the anode and cathode electrodes by means of microprobes;

FIG. 51 is a linear graph of a third current-voltage range of the electrochemical rectifier of Example 12, as measured by an HP-4145 parameter analyzer with the sweep signals obtained from the anode and cathode electrodes by means of microprobes;

FIG. 52 is a log-log graph of the forward bias current-voltage characteristics of the rectifier of Example 12;

FIG. 53 is a log-log graph of the reverse bias current-voltage characteristics of the rectifier of Example 12;

FIG. 54 is an illustration of an electrochemical rectifier comprising a silaborane film produced in accordance with Example 13;

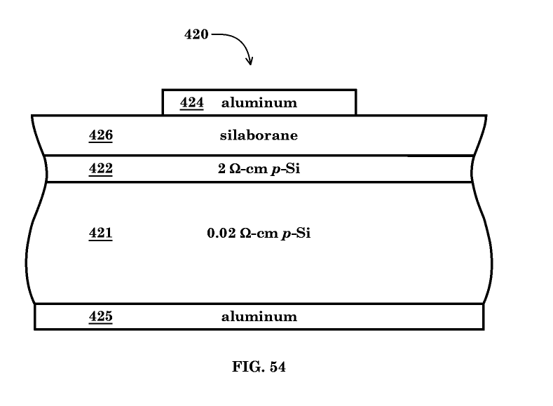

FIG. 55 is a linear graph of current-voltage characteristics of the electrochemical rectifier of FIG. 54, (Example 13) as measured by an HP-4145 parameter analyzer with the sweep signals obtained by a mercury probe;

FIG. 56 is a linear graph of a second range of current-voltage characteristics of the electrochemical rectifier of FIG. 54 (Example 13), as measured by an HP-4145 parameter analyzer with the sweep signals obtained by a mercury probe;

FIG. 57 is a log-log graph of the forward bias current-voltage characteristics of the rectifier of Example 13.

FIG. 58 is a log-log graph of the reverse bias current-voltage characteristics of the rectifier of Example 13;

FIG. 59 is an illustration of an oxysilaborane film deposited on a substrate comprising gold, titanium, silicon dioxide and gallium arsenide as described in Example 14.

FIG. 60 is an x-ray photoelectron spectroscopy (XPS) depth profile of the oxysilaborane film as deposited in Example 14;

FIG. 61 is a SIMMS depth profile measuring the gold atomic concentrations in the film of Example 14;

FIG. 62 is an illustration of metal electrodes deposited on the device of Example 14;

FIG. 63 is a graph of the current-voltage characteristics of the oxysilaborane film of Example 14.

### DESCRIPTION OF THE PREFERRED EMBODIMENTS

A new type of solid composition of matter derived from the heating of boron and silicon hydrides in the presence of hydrogen and, optionally, an oxidizing chemical agent is disclosed. The compositional range of preferred materials, hereinafter referred to as “picocrystalline oxysilaboranes” and represented by the formula “(B₁₂H₄)ₓSi_{y}O_{z}”, comprises (B₁₂H₄)₄Si₄ at an extreme and (B12²⁻H₄)₂Si₄O₂²⁺ at the other extreme, with x, y, and z being numbers within the respective ranges of: 2≦x≦4, 3≦y≦5 and 0≦z≦2. Picocrystalline oxysilaborane (B₁₂H₄)ₓSi_{y}O_{z} is itself contained in a broader compositional range of novel materials also discussed here for the first time and hereinafter referred to as “oxysilaboranes” and represented by “(B₁₂)ₓSi_{y}O_{z}H_{w}”, with w, x, y, and z being numbers within the respective ranges of: 0<w≦5, 2≦x≦4, 2≦y≦5 and 0≦z≦3.

The picocrystalline oxysilaboranes of this invention are transparent solids believed to be constituted by a continuous random network of polymorphic unit cells that satisfy a modification of the rules established by Zachariasen, “The Atomic Arrangement in Glass,” Journal of the American Chemical Society, Vol. 54, 1932, pp. 3841-3851. Zachariasen focused on oxide glasses and, more specifically, on amorphous SiO₂ and amorphous B₂O₃. Zachariasen developed that amorphous SiO₂ is formed by a continuous random network of SiO₄ tetrahedra. Similarly, the picocrystalline oxysilaboranes are believed to be formed by a continuous random network of polyhedra but with a highly symmetrical boron icosahedron at the polyhedral corners.

### Example 1

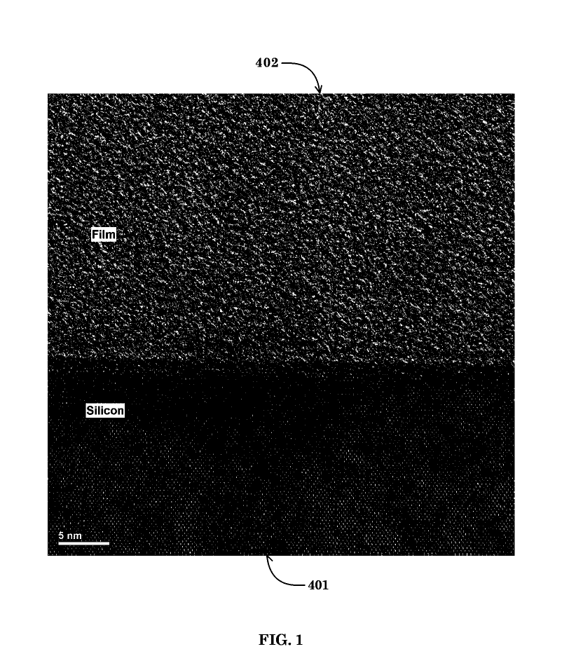

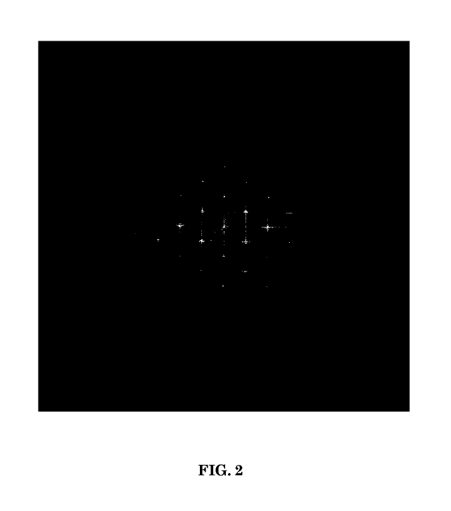

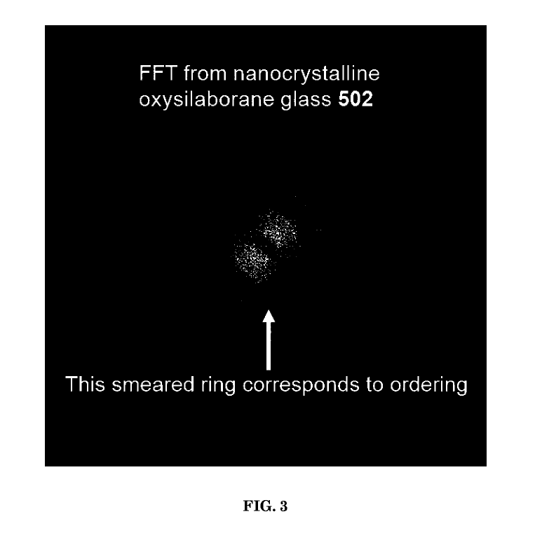

FIG. 1 shows a micrograph obtained by high-resolution transmission electron microscopy (HRTEM) of a picocrystalline borane solid 402 deposited on a monocrystalline (001) silicon substrate 401. The interfacial layer 403 is due to the specific conditions of its deposition. An HRTEM fast Fourier transform (FFT) image of the monocrystalline silicon substrate 401 is shown in FIG. 2. A similar FFT image of the picocrystalline borane solid 402 is shown in FIG. 3. Whereas the FFT image of the silicon substrate 401 in FIG. 2 is characteristic of a monocrystalline (001) silicon lattice with a long-range periodic translational order, the FFT image of the picocrystalline solid 402 within FIG. 3 exhibits a short-range order that is not characteristic of either a monocrystalline lattice or an amorphous solid. The various types of order will now be further defined.

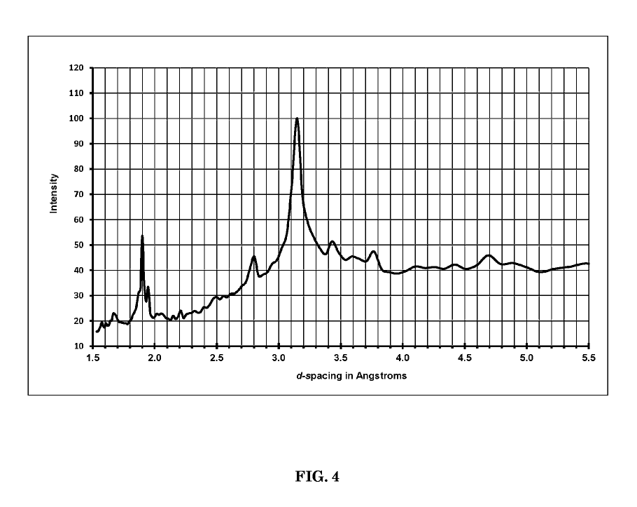

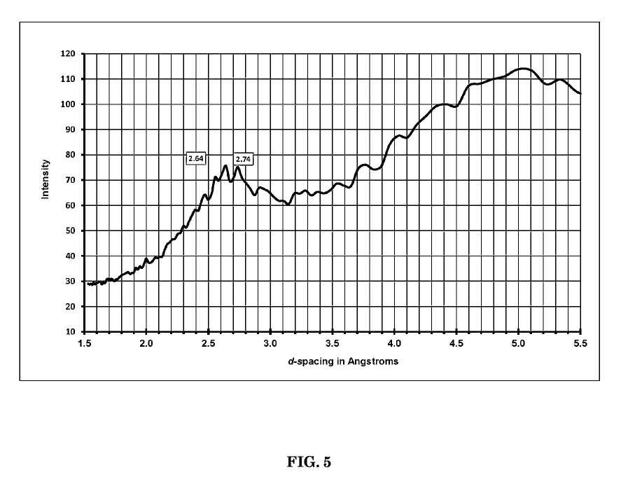

To illustrate the short-range order of the picocrystalline borane solid 402, the HRTEM diffraction intensity of the monocrystalline silicon substrate 401 is graphed in FIG. 4 in terms of the interplanar lattice d-spacings between parallel Bragg planes of atoms supporting a constructive electron wave interference. The highest-intensity peak in FIG. 4 is associated with the interplanar lattice d-spacing of 3.135 Å between parallel {111} planes of atoms in the monocrystalline silicon substrate 401. The other high-intensity peak in FIG. 4 is associated with an interplanar d-spacing of 1.920 Å between parallel {220} planes of atoms in the monocrystalline silicon substrate 401. No singular high-intensity peak exists in the FFT diffraction pattern of the picocrystalline borane solid 402 shown in FIG. 5, which was similarly obtained by HRTEM microscopy

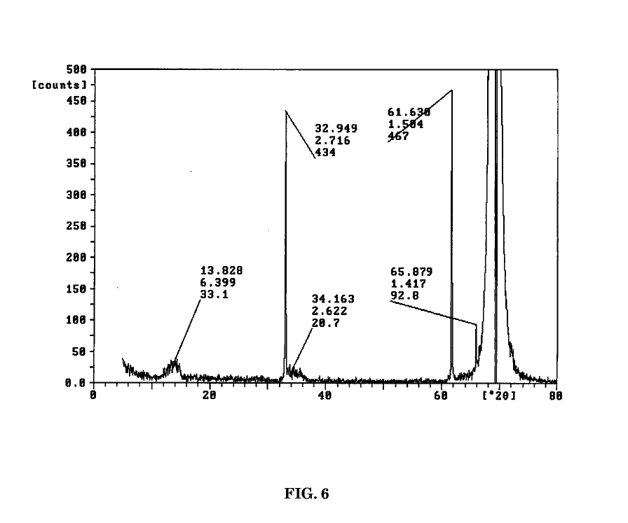

The broadened circular ring in the FFT image of the picocrystalline borane solid 402 in FIG. 3 can be related to broadened interplanar lattice spacings between d=2.64 Å and d=2.74 Å in FIG. 5. In order to more fully understand the significance of this smeared ring, it is purposeful to consider a conventional ω-2θ x-ray diffraction (XRD) pattern of a thin picocrystalline borane solid, as shown in FIG. 6. In a conventional ω-2θ XRD diffraction pattern, the angle of incidence ω of the x-ray beam and the angle 2θ of the diffracted x-ray beam are held relatively constant and collectively varied together over the x-ray diffraction angle 2θ. By so doing, a set of regularly-spaced lattice planes results in a sharp diffraction peak. The thin picocrystalline borane solid scanned in FIG. 6 was also deposited over a monocrystalline (001) silicon substrate. The high-intensity peaks shown in FIG. 6 are associated with x-ray diffraction from regularly-spaced silicon lattice planes.

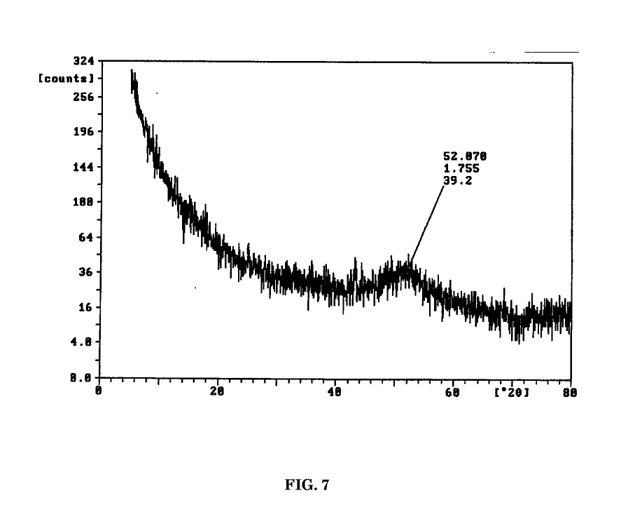

There are two broadened diffraction peaks centered near 2θ=13.83° and 2θ=34.16° in FIG. 6. Both of these low-intensity broadened diffraction peaks are associated with the thin picocrystalline borane solid. In order to separate the diffraction peaks associated with the thin film from those associated with the substrate, grazing-incidence x-ray diffraction (GIXRD) spectroscopy was utilized. This type of spectroscopy is also referred to as glancing-angle x-ray diffraction. Both of these two terms will be utilized interchangeably. A GIXRD scan of the same pico-crystalline borane solid scanned in FIG. 6 is shown in FIG. 7. For a low glancing angle co, GIXRD diffraction peaks are due to the regularly-spaced lattice planes of atoms in the thin picocrystalline borane solid—not the silicon substrate.

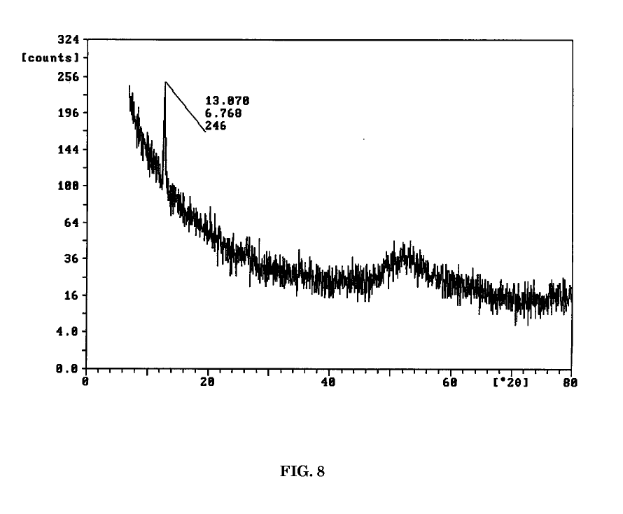

The picocrystalline borane solid appears to be an amorphous film in FIG. 7 except, perhaps, for a short-range order due to broadened diffraction peaks near the diffraction angle of 2θ=52.07°. In the GIXRD scan of the picocrystalline borane solid shown in FIG. 8, the fixed angle of incidence of the x-ray beam was ω=6.53° and the x-ray detector was varied over a range of diffraction angles from 2θ=7.0° to 2θ=80°. A sharp low-intensity x-ray peak exists at 2θ=13.07° in FIG. 8. This x-ray diffraction peak corresponds to an interplanar lattice d-spacing of d=6.76 Å, which is contained in the broad range of low-intensity x-ray peaks near 2θ=13.83° in FIG. 6. This x-ray diffraction peak relates to the Bragg condition of the fixed x-ray angle of incidence ω=6.53°. If the fixed x-ray angle of incidence ω is changed, a different Bragg peak is obtained in correspondence to the new x-ray angle of incidence ω in some other GIXRD scan. This range of low-intensity x-ray peaks, related to the x-ray angle of incidence ω in GIXRD scans, proves a picocrystalline borane solid is not amorphous.

However, analysis further establishes that a picocrystalline borane solid is not polycrystalline. A polycrystalline film is comprised of a large number of crystalline grains that are randomly ordered, such that all sets of regular inter-planar lattice spacings are brought into the Bragg condition in any GIXRD scan by virtue of the random ordering of the polycrystalline grains. This is not the case in FIGS. 7-8. The possible explanation of the physical structure of a picocrystalline borane solid is posited by reconciling experimental diffraction data with a belief that the boron icosahedra retain a nearly-symmetrical nuclear configuration.

### Various Types of Order in the Picocrystalline Oxysilaboranes

Preferred embodiments of this invention involve a type of order not known in the prior art. Long-range periodic translational order is defined as the regular repetition of a certain invariant arrangement of atoms, known as a unit cell, over space so as to form a translationally invariant tiling in a regular array of atoms well beyond first- and second-nearest neighbor atoms. Monocrystalline and polycrystalline materials possess a long-range periodic translational order in space. A periodic repetition of atomic positions is preserved over the entire space of a monocrystalline material. In a polycrystalline material, a periodic repetition of atomic positions is preserved over the limited, finite space of grains that can be themselves arbitrarily oriented over the entire space of polycrystalline materials. A nanocrystalline material is a special polycrystalline material wherein the grain sizes range between a maximum of 300 nm and a minimum of 300 pm.

Short-range periodic translational order is defined as a repetition of atomic positions over a space confined to only first- and second-nearest neighbor atoms. The radii of isolated neutral atoms range between 30 and 300 pm. As the result, a picocrystalline material is defined as a material exhibiting a short-range periodic translational order limited to repeating atomic positions in finite groups of first- and second-nearest neighbor atoms. An amorphous material is defined as a material void of any regularly repeating arrangements of atoms, so as to be incapable of supporting any constructive interference of x-rays and electrons.

It might appear that these definitions of various types of crystalline materials fully describe the allowable order of repeating atomic positions in space. But, these definitions are limited in the sense that they are based strictly upon repeating atomic positions in space. These definitions must be extended to comprehend a quantum dot, which is defined as a cluster of atoms in which a quantization of energy levels occurs in a manner similar to atoms. The size of a typical quantum dot in the prior art is on the order of 10 nm. The above noted definitions of the various types of crystalline materials are independent of any energy quantization. This leads to a new definition. AS used herein a picocrystalline quantum dot is a cluster of atoms, of a size less than 300 pm, that are mutually bonded together to support a short-range periodic translational order and an internal discrete quantization of energy levels.

Picocrystalline quantum dots are taken to be artificial atoms capable of chemically bonding with other atoms in supramolecular compounds. A specific type of picocrystalline quantum dot utilized in embodiments of this invention is a boron icosahedron with a nearly-symmetrical nuclear configuration that escapes Jahn-Teller distortion. The boron icosahedra in most known boron-rich solids exhibit a broken icosahedral symmetry due to Jahn-Teller distortion, such that the first and second-nearest neighbor boron atoms do not reside in repeating spatial positions capable of supporting a short-range periodic translational order. Most boron icosahedra in the prior art are bonded by the molecular orbitals derived by Longuet-Higgins and Roberts in the paper entitled “The Electronic Structure of an Icosahedron of Boron,” Proceedings of the Royal Society A, Vol. 230, 1955, p. 110.

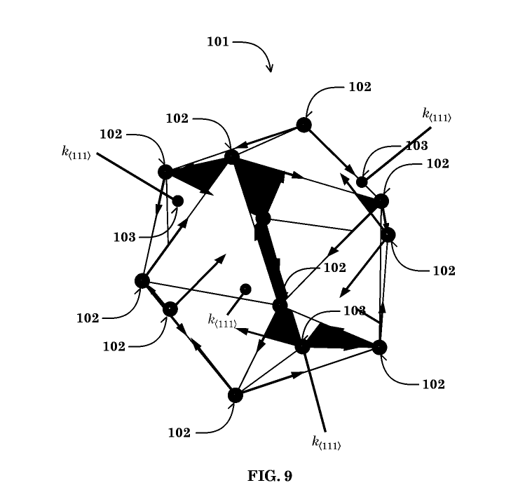

In their analysis, Longuet-Higgins and Roberts never geometrically located the electrons of three-center bonds by means of the icosahedral symmetry operations. The inventor has constructed a molecular orbital analysis that locates the three center bonds and predicts a boron icosahedron 101 comprising 12 boron nuclei 102, with a symmetrical nuclear configuration that can be formed by 24 delocalized atomic orbitals so as to result in a nearly-symmetrical spheroid with all displacement ideally restricted to periodic vibrations along the four k₍₁₁₁₎ wave vectors shown in FIG. 9. An electric quadrupole moment along the k₍₁₁₁₎ wave vectors induces an electric dipole moment in the hydrogen atoms, such that the four hydrogen nuclei 103 bond by a Debye force, as shown in FIG. 9. The Debye force aligns the valence electrons of the hydrogen nuclei 103 along a k₍₁₁₁₎ wave vector.

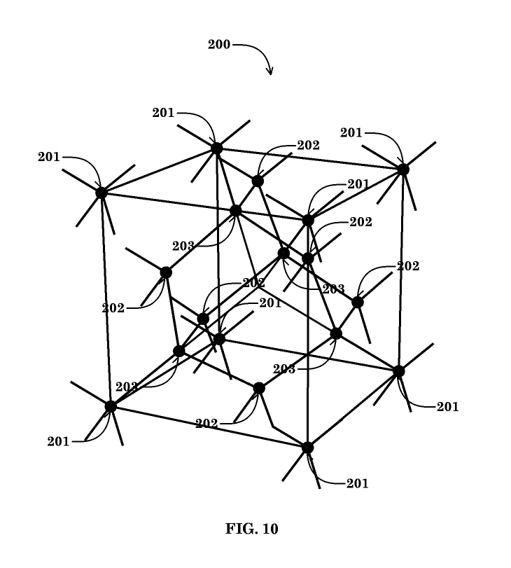

The self-assembly of the picocrystalline oxysilaboranes involves the selective replacement of silicon atoms in a monocrystalline silicon lattice by boron icosahedra with a symmetrical nuclear configuration in a picocrystalline quantum dot. To further illustrate the order present in picocrystalline oxysilaboranes, the characteristic order of the unit cell of monocrystalline silicon prior to such substitution will be explained. The monocrystalline silicon unit cell 200 in FIG. 10 is comprised of 8 silicon vertex atoms 201, 6 silicon face-center atoms 202, as well as 4 silicon basis atoms 203. The basis atoms 203 reside along a (111) cubic body diagonal in a tetrahedral arrangement. The monocrystalline silicon unit cell 200 is periodically translated over space so as to form a monocrystalline silicon lattice in which all silicon vertex atoms 201 and all silicon face-center atoms 202 are covalently bonded to, and only to, silicon basis atoms 203 along a (111) crystal orientation. The resultant mono-crystalline silicon lattice has a long-range periodic translational order in terms of cubic unit cells of ˜543 pm along each edge, without any (100) chemical bonds.

Per the normal crystallographic convention, any orientation along, or parallel to, any cubic edge is generally represented by (100). Any particular (100) orientation, e.g. the [010] orientation along the positive y-axis, will be specifically denoted. A cubic face, or a plane parallel to a cubic face, is generally represented by {100}. A particular {100} plane, e.g. the xz-plane normal to the [010] direction, is represented by (010). A particular (100) orientation, e.g. the [010] orientation, is always normal to the corresponding {100} plane, viz. the (010) plane in this case. By further convention, any orientation along, or parallel to, a cubic body diagonal is represented by (111). There are two classes of icosahedral faces: 8 icosahedral faces are constituted by {111} planes normal to a (111) cubic body diagonal and 12 icosahedral faces are constituted by planes which intersect in pairs along a (100) orientation. Three-center bonds only exist along edges of the {111} planes.

The invariance of the dimensions of the monocrystalline silicon unit cell 200 is maintained in the presence of extensive electron eigenstate changes by a displacement of the silicon basis atoms 203 along a (111) crystal orientation. It is very significant that the silicon vertex atoms 201 and silicon face-center atoms 202 are motionless while the silicon basis atoms 203 can be displaced along a (111) cubic body diagonal. A change in eigenstate of any valence electron eigenfunction involves a change in extension of the valence electron eigenfunction. The diamond lattice of monocrystalline silicon supports extensive changes in valence electron eigenstates, without mechanical work, due to an invariant lattice constant of the constituent unit cells. The basis atoms 203 support a (111) bond orientation.

The practical means to exploit the ability of a monocrystalline silicon lattice to support extensive changes in eigenstate in the absence of any mechanical work is fundamentally limited by its structure. First, monocrystalline silicon can only be epitaxially deposited over monocrystalline silicon substrates. Secondly, the termination of a monocrystalline silicon lattice, in order to electrically contact it, results in Tamm-Shockley states that pin the electrochemical potential within the forbidden energy region between the bottom of the conduction band and top of the valence band. This pinning of the electrochemical potential results in a rectifying contact independent of the metal work function of electrodes. See Bardeen, by way of example, “Surface States at a Metal Semi-Conductor Contact,” Phys. Rev. 10, No. 11, 1947, p. 471. Thus it would be highly desirable for the Tamm-Shockley interface state density to be reduced.

By well-known processing techniques, a substantial reduction in the Tamm-Shockley interface state density can be achieved by terminating crystalline silicon regions with amorphous silicon dioxide films such that the surface electrochemical potential can be modulated, in device operation, throughout the forbidden energy region. A field-effect transistor uses the ability to modulate the electrical conductivity of a monocrystalline silicon surface by capacitively-coupled electrodes via an intervening silicon dioxide thin-film. However, the silicon dioxide must be removed from semiconductor contact regions due to the high resistivity of silicon dioxide ˜10¹⁶ Ω-cm. In order to reduce Tamm-Shockley states in the semiconductor contact zones, the semiconductor surface is often degenerately doped, such that the electrochemical potential is pinned in the conduction or valence energy band.

A metal or a silicide can be alloyed to the degenerate semiconductor surface, such that mobile charges can tunnel through a potential barrier into the isotype homojunction. Under low-level injection, the isotype homojunction acts as an ohmic contact to any high-resistivity semiconductor region. However, this type of ohmic contact prevents the employment of a monocrystalline semiconductor in an electrochemical rectifier wherein the electrochemical potential varies between the external electrodes. This deficiency can be remedied by the incorporation of a borane molecule B₁₂H₄ 101 with an ideally symmetrical nuclear configuration into the monocrystalline silicon unit cell 200 in FIG. 10, so as to form a picocrystalline unit cell with a bond-orientational order compatible with monocrystalline silicon.

### Example 2

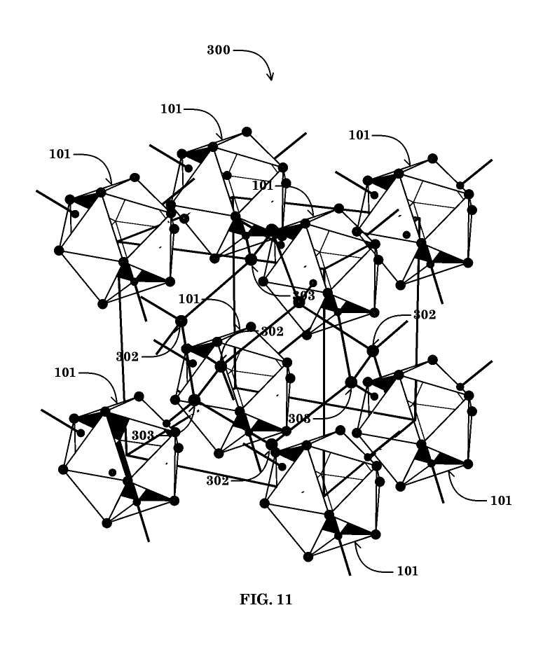

A diamond-like picocrystalline silaborane unit cell 300 is constructed by replacing each silicon vertex atom 201 in the monocrystalline silicon unit cell 200 with a borane molecule B₁₂H₄ 101 per FIG. 11. The 8 borane molecules B₁₂H₄ 101 at the vertices of the silaborane unit cell 300 in FIG. 11 are shared amongst 8 picocrystalline silaborane unit cells 300 in a solid lattice. As the result, a periodic translation of the picocrystalline silaborane unit cell 300 over space results in a solid picocrystalline silaborane (B₁₂H₄)Si₇ lattice, which effectively behaves as a self-assembled diamond-like picocrystalline lattice structurally similar to mono-crystalline silicon. Borane molecules B₁₂H₄ 101 replace the 8 silicon vertex atoms 201 in the picocrystalline silaborane (B₁₂H₄)Si₇ lattice since the boron nuclei 102 remain motionless in the symmetrical nuclear configuration while the hydrogen nuclei 103 vibrate along the k₍₁₁₁₎ wave vectors of the four (111) threefold axes.

Per Zachariasen, the SiO4 tetrahedra forming the continuous random network of amorphous silicon dioxide SiO₂ share corners, but not edges or faces, such that each oxygen atom has only two nearest-neighbor silicon atoms. Unlike quartz, the bond-angles between any given oxygen atom and two nearest-neighbor silicon atoms are not identical, such that the silicon-oxygen bond-angle randomly varies over the continuous network of amorphous silicon dioxide SiO₂. Due to the random variation in the silicon-oxygen bond-angle, amorphous silicon dioxide does not exhibit a long-range periodic translational order capable of supporting Bragg peaks in a diffraction pattern due to constructive wave interference.

Zachariasen stated in 1932 that: “An oxide glass may be formed (1) if the sample contains a high percentage of cations which are surrounded by oxygen tetrahedra or by oxygen triangles; (2) if these tetrahedra or triangles share only corners with each other and; (3) if some oxygen atoms are linked to only two such cations and do not form further bonds with any other cations.” By a generalization of Zachariasen's rules, the picocrystalline oxysilaboranes can be established as a novel type of borane solid. Whereas an oxide glass is formed by a continuous random network of oxygen tetrahedra or oxygen triangles, the picocrystalline oxysilaboranes constitute a solid formed by a continuous random network of borane hexahedra, which, by definition, form a hexahedron with a borane molecule B₁₂H₄ 101 or a borane dianion B₁₂²⁻H₄ 101 at each of the hexahedral corners. Whereas the monocrystalline silicon unit cell 200 in FIG. 10 is a regular hexahedron (cube), the oxysilaborane unit cell 300 shown in FIG. 11 is an irregular hexahedron.

Whereas Zachariasen established the atomic arrangement of an oxide glass by means of a continuous random network of polymorphic oxygen tetrahedra or polymorphic oxygen triangles, the atomic arrangement of a borane solid will be established now in terms of a continuous random network of polymorphic borane hexahedra 300. The eight corners of the borane hexahedron 300 shown in FIG. 11 are comprised of corner picocrystalline quantum dots 101 that are constituted by an icosahedral borane molecule B₁₂H₄101 or borane dianion B12²⁻H₄ 101. Each corner picocrystalline quantum dot 101 is bonded to four, and only four, tetravalent atoms 303, which are always surrounded by eight corner picocrystalline quantum dots 101. Preferred tetravalent atoms are carbon, silicon, and germanium atoms.

Each tetravalent atom 303 bonds to one or more face-center particle 302 in the borane hexahedron 300 shown in FIG. 11. The face-center particle 302 can be any of, but not limited to: a tetravalent atom such as silicon; a hexavalent atom such as oxygen; a borane molecule; B₁₂H₄, or a borane dianion B12²⁻H₄. With the help of the borane hexahedron 300 shown in FIG. 11, the atomic arrangement of a borane solid can be understood by changes in Zachariasen's rules for an oxide glass. First of all, four tetravalent atoms 303 are always surrounded by 8 corner picocrystalline quantum dots 101 in the borane solid. Secondly, the borane hexahedra 300 always share corner picocrystalline quantum dots 101 in the random network. The centroid of each corner picocrystalline quantum dot 101 is, ideally, motion-invariant. Thirdly, each corner picocrystalline quantum dot 101 bonds to four, and only four, tetravalent atoms 303 along a (111) bond orientation.

Unlike an oxide glass, picocrystalline oxysilaboranes form a borane solid by a continuous random network of borane hexahedra 300 in which the hexahedral edges and faces are shared, in addition to the eight corners. Whereas the borane hexahedron 300 is represented as a cube in FIG. 11, the borane hexahedra 300 comprising the continuous network of the picocrystalline oxysilaboranes are irregular hexahedra that cannot be associated with a cubic lattice constant. There is a fundamental physical reason that the picocrystalline oxysilaboranes form a borane solid comprised of irregular borane hexahedra 300. Zachariasen pointed out that vitreous glasses tend to form a continuous network related to a crystal, albeit a network incapable of supporting a long-range periodic translational order.

The picocrystalline oxysilaboranes tend to form a borane solid with a continuous network quite similar to that of monocrystalline silicon, albeit a continuous random network in which certain silicon atoms are selectively replaced by picocrystalline quantum dots 101 comprising boron icosahedra with a symmetrical nuclear configuration. By preserving the fivefold rotational symmetry of a regular boron icosahedron, it is impossible for the picocrystalline oxysilaboranes to support any long-range periodic translational order. A borane solid constituted by the picocrystalline oxysilaboranes is hereinafter, more generally, referred to as a pico-crystalline borane solid. A precise definition of a picocrystalline borane solid is provided after attributes of such a solid are described by actual examples. By so doing, the picocrystalline oxysilaboranes will be established as a highly novel and useful boron rich amalgamation of monocrystalline silicon and amorphous silicon dioxide.

The 20C₃ icosahedral symmetry operations leave any regular icosahedron unchanged under an 120° rotation about an axis connecting the midpoints of the ten pairs of parallel (albeit inverted) triangular faces. For a regular boron icosahedron with an edge of 1.77 Å, the interplanar lattice spacing of the parallel triangular faces is d=2.69 Å. This intraicosahedral lattice spacing corresponds to a diffraction angle of 2θ=33.27° for 1.54 Å x-rays (which is the x-ray wavelength used in all XRD scans in the figures hereinabove). This diffraction angle is contained in the broadened, low-intensity diffraction peaks at 2θ=34.16° in the ω-2θ XRD scan in FIG. 6—which, in turn, are related to the smeared circular electron diffraction ring in FIG. 3. It is next purposeful to provide a possible explanation for the broadening of the x-ray and electron diffraction peaks and rings.

The symmetrical nuclear configuration of boron icosahedra assumes that the boron nuclei at the 12 icosahedral vertices are all the same. This is not actually the case. There exist two naturally-occurring stable boron isotopes, ¹⁰₅B and ¹¹₅B, with spherically deformed nuclei. An oblate spheroidal nucleus exhibits a negative electric quadrupole moment while a prolate spheroidal nucleus exhibits a positive electric quadrupole moment. Of the 267 stable nuclides, boron ¹⁰₅B is the stable nuclide with the greatest nuclear electric quadrupole moment per nucleon, which tends to destabilize the boron nuclei. Boron ¹⁰₅B exhibits a nuclear angular momentum 3/2 [symbol] , as well as, a large positive nuclear electric quadrupole moment of +0.111×10⁻²⁴ e-cm². Boron ¹¹₅B exhibits a nuclear angular momentum 3/2 [symbol] , as well as, a positive nuclear electric quadrupole moment of +0.0355×10⁻²⁴e-cm².

The naturally-occurring isotopes of boron are −20% ¹⁰₅B and −80% ¹¹₅B. Assuming, for present purposes, that the boron nuclei comprising the boron icosahedra of the picocrystalline oxysilaboranes of this invention are distributed per the naturally-occurring isotopic ratio, the center of gravity of the boron nuclei is shifted from the geometric center of the icosahedral faces. This tends to deform the symmetrical nuclear configuration of boron icosahedra. This deformation can be related to an isotopic enrichment discussed by Nishizawa, “Isotopic Enrichment of Tritium by Using Guest-Host Chemistry,” in Journal of Nuclear Materials, Vol. 130, 1985, p. 465. Nishizawa employed a guest-host thermochemistry to eliminate radioactive tritium from waste water at a nuclear facility by a crown ether and an ammonium complex. Ammonium NH₃ weakly trapped by a crown ether exists in a symmetrical triangle with the three hydrogen nuclei at the triangle corners and the center of gravity at the geometric center. The distance between the hydrogen nuclei along the triangular edges is 1.62 Å. If one hydrogen atom is replaced by a tritium atom, the center of gravity is shifted by 0.28 Å towards the tritium atom.

The shift of the center of gravity away from the triangular geometric center in tritiated ammonium is associated with a decrease in Gibbs free energy due to an increase in entropy. It necessarily follows that an isotopic enrichment of tritiated ammonium (weakly trapped by a crown ether) constitutes a spontaneous thermochemical reaction in which the decrease in Gibbs free energy results from a positive increase in entropy which exceeds the positive increase in enthalpy. A similar condition can be established in the picocrystalline oxysilaboranes.

The geometric distortion due to the mixture of boron isotopes ¹⁰₅B and ¹¹₅B, in boron icosahedra comprising the picocrystalline oxysilaboranes, causes a broadening of the Bragg peaks associated with the intraicosahedral constructive x-ray diffraction patterns due to the ten sets of nearly-parallel plane faces of the constituent boron icosahedra. However, it is believed that this isotopic distortion is similarly preserved in most of the boron icosahedra, such that Bragg peaks are associated with intericosahedral constructive x-ray diffraction patterns between parallel planes formed by boron icosahedra at the corners of a continuous random polyhedral network. The distance between the body centers of the corner boron icosahedra varies randomly, such that sharp Bragg peaks occur between parallel icosahedral faces for each x-ray angle of incidence over a range near 2θ=13.83°.

A nanocrystalline solid is typically taken to be a polycrystalline solid with small grains, with the grain size being less than 300 nm. As the grain size is reduced, then the periodic translational order is of a shorter range and the x-ray diffraction peaks are broadened. Whereas any typical nanocrystalline material is void of any long-range order, the picocrystalline oxysilaboranes of this invention possess a short-range periodic translational order along with a long-range bond-orientational order that is believed to be due to the self-alignment of boron icosahedra with a nearly-symmetrical nuclear configuration. By a definition herein, a picocrystalline borane solid is a solid, comprised of at least boron and hydrogen, that exhibits a long-range bond-orientational order due to sharp x-ray diffraction peaks when subjected to grazing-incidence x-ray diffraction (GIXRD).

In order to understand the long-range bond-orientational order that characterizes the picocrystalline oxysilaboranes, it is purposeful to focus on the quantum dots. The picocrystalline quantum dots comprising the picocrystalline oxysilaboranes are boron icosahedra with a nearly-symmetrical nuclear configuration, so as to support a short-range periodic translational order. The ten pairs of parallel faces of the picocrystalline quantum dots are ideally separated by d=269 pm, which supports a broad intraicosahedral x-ray diffraction peak at 2θ=33.27°. As discussed hereinabove, the intraicosahedral x-ray diffraction peaks within any picocrystalline quantum dot are broadened by a mixture of the boron isotopes ¹⁰₅B and ¹¹₅B. It is purposeful to more exactly define as to what is meant by “broad” and “sharp” x-ray diffraction peaks in preferred embodiments of this invention.

Any sharp x-ray diffraction peak is characterized by a peak width at half intensity that is at least ten times smaller than the peak height. Conversely, a broad x-ray diffraction peak is characterized by a peak width at half intensity that is greater than half the peak height. The x-ray diffraction peak at 2θ=52.07° in FIG. 7 is a broad x-ray diffraction peak characteristic of very small grains. The x-ray diffraction peak at 2θ=34.16° in the w-2θ XRD scan in FIG. 6 is a broad x-ray diffraction peak due to a constructive intraicosahedral x-ray diffraction from picocrystalline quantum dots. All of the embodiments of this invention comprise picocrystalline quantum dots which support a broad x-ray diffraction peak near 2θ=33.27°. The extended three-dimensional network of the picocrystalline oxysilaboranes is formed by a translation through space of an irregular polyhedron.

The fivefold symmetry of a regular icosahedron is incompatible with the fourfold symmetry of a regular hexahedron (cube), such that it is impossible to periodically translate a regular hexahedral unit cell, with icosahedral quantum dots at the vertices, over space in a translationally invariant manner. Symmetry breaking must occur in the irregular borane hexahedra 300 shown in FIG. 11. In most known boron-rich solids in the prior art, the fivefold icosahedral symmetry is broken by Jahn-Teller distortion—such that the intericosahedral bonds tend to be stronger than the intraicosahedral bonds. It is for this reason that the boron-rich solids in the prior art are referred to as inverted molecules. The elimination of fivefold icosahedral symmetry, by icosahedral symmetry breaking, reduces the spherical aromaticity associated with bond delocalization in boron icosahedra.

The fivefold rotational symmetry of the picocrystalline quantum dots 101 is maintained, such that the fourfold symmetry of the irregular borane hexahedra 300 is therefore broken. Each irregular borane hexahedron 300 is formed by artificial atoms 101 at the hexahedral corners. It is to be understood that an artificial atom 101 is a picocrystalline quantum dot formed by boron icosahedra, with a nearly-symmetrical nuclear configuration preserving a fivefold rotational symmetry. Although the fivefold rotational symmetry cannot be directly observed by x-ray or electron diffraction, novel electronic and vibrational properties due to the fivefold rotational symmetry of the artificial atoms 101 can be observed. The artificial atoms 101 are comprised by a regular arrangement of first- and second-nearest neighbor boron atoms that supports a short-range translational order.

Similar to natural atoms, the artificial atoms 101 of the picocrystalline oxysilaboranes confine a discrete quantization of energy levels in a region of space less than 300 pm. However, the discrete energy levels of the artificial atoms 101 are fundamentally different from the discrete energy levels of natural atoms. At issue are spectroscopic principles of conventional chemistry. The spectroscopic principles are framed by references to a book by Harris and Bertolucci, Symmetry and Spectroscopy, Oxford Univ. Press, 1978. On pages 1-2 of their book, Harris and Bertolucci emphasized that: “Light of infrared frequencies can generally promote molecules from one vibrational energy level into another. Hence, we call infrared spectroscopy vibrational spectroscopy. Visible and ultraviolet light are much more energetic and can promote the redistribution of electrons in a molecule such that the electronic potential energy of the molecule is changed. Hence, we call visible and ultraviolet spectroscopy electronic spectroscopy.”

In the artificial atoms 101 of the picocrystalline oxysilaboranes, the rotational, vibrational, and electronic degrees of freedom are totally intertwined in rovibronic energy levels which support a redistribution of electrons in response to microwave radiation. A redistribution of electrons between microwave energy levels is due to an internal quantization of energy levels arising from the fivefold rotational symmetry, of a nearly-symmetrical icosahedron, capable of supporting a broadened diffraction peak at a diffraction angle 2θ=33.27° that corresponds to an ideal spacing of d=269 pm between opposite pairs of icosahedral faces. Unlike natural atoms, the artificial atoms 101 have a detectable infrastructure.

Since the corners of the irregular borane hexahedra 300 of the picocrystalline oxysilaboranes are occupied by artificial atoms 101, intericosahedral x-ray diffraction peaks are associated with nearest-neighbor artificial atoms 101. Referring to FIG. 11, the corresponding icosahedral faces of the artificial atoms 101 are ideally self-aligned in picocrystalline oxysilaborane (B₁₂H₄)xSiyOz over the preferred compositional range, wherein 2≦x≦4, 3≦y≦5 and 0≦z≦2. Due to the symmetry breaking of the irregular borane hexahedra 300, the self-alignment of the icosahedral faces of the artificial atoms 101 is maintained in the presence of a random separation between the icosahedral body centers of the artificial atoms 101. The alignment of a natural atom in molecules is typically described in terms of the bond angle of the atomic valence electrons. This property relates to the fact that a natural atom is void of any apparent nuclear infrastructure.

The artificial atoms 101 in the picocrystalline oxysilaboranes possess an infrastructure associated with a nearly-symmetrical icosahedron, with a boron nucleus 102 at each icosahedral vertex per FIG. 9. In order to maintain a nearly-symmetrical nuclear configuration, the boron nuclei 102 of an artificial atom 101 are chemically bonded by three-center bonds, such that the peak electron density ideally exists in the center of the eight icosahedral faces normal to the four k(111) wave vectors in FIG. 9. It is very significant that the artificial atoms 101 comprise a caged boron icosahedron with no radial boron valence electrons. As a result, the artificial atoms 101 can bond to natural atoms in picocrystalline oxysilaboranes by means of hydrogen atoms that are, in turn, bonded by a Debye force.

The self-alignment of the artificial atoms 101 in the irregular borane hexahedra 300 results in the valence electrons of the hydrogen nuclei 103 being aligned along the k₍₁₁₁₎ wave vectors. Since the four valence electrons of the tetravalent atoms 303 in the irregular borane hexahedra 300 are aligned along a k(111) wave vector, then the artificial atoms 101 are covalently bonded to the tetravalent atoms 303 along k₍₁₁₁₎ wave vectors by means of hydrogen atoms. The bond angle between the artificial atoms 101 and the natural tetravalent atoms 303 is aligned along k₍₁₁₁₎ wave vectors if the icosahedral faces of the artificial atoms 101 are self-aligned and the icosahedral body centers randomly vary over a finite range.

The self-alignment of the icosahedral faces and the random spatial variations of the icosahedral body centers of artificial atoms 101 can be evaluated by x-ray diffraction spectroscopy. This is due to a fact that, unlike natural atoms, the artificial atoms 101 possess an infrastructure of periodically repeating first- and second-nearest neighbor boron atoms. The short-range periodic translational order of the artificial atoms 101 is detected by intraicosahedral diffraction peaks associated with an interplanar spacing of d=269 pm between parallel icosahedral faces. The short-range periodic translational order of the picocrystalline oxysilaboranes is characterized by a broad x-ray diffraction peak, under conventional ω-2θ x-ray diffraction, that exists, at least partly, within the diffraction angle range 32°≦2θ≦36°. The short-range periodic translational order of the artificial atoms 101 supports the detection of the corners of the irregular borane hexahedra 300 forming the picocrystalline oxysilaboranes over a preferred compositional range.

Intericosahedral x-ray diffraction peaks, due to parallel faces within nearest-neighbor artificial atoms 101, collectively result in a broad x-ray diffraction peak, under conventional x-ray diffraction, that is included in the diffraction angle range 12°≦2 θ≦16°. In a conventional w-2θ x-ray diffraction, the x-ray angle of incidence w and the diffraction angle 2θ are held relatively constant and, then, collectively varied over a very wide range of diffraction angles. Conventional w-2θ x-ray diffraction, by itself, cannot establish the self-alignment of artificial atoms 101 in the picocrystalline oxysilaboranes. This deficiency can be remedied when conventional w-2θ x-ray diffraction is further augmented by a grazing-incidence x-ray diffraction (GIXRD). Whereas a number of Bragg conditions can be detected under conventional w-2θ x-ray diffraction, only one specific Bragg condition exists in GIXRD diffraction for each fixed x-ray angle of incidence w.

For any given fixed x-ray angle of incidence w, in the range 6°<w<8°, a sharp x-ray diffraction peak exists in the picocrystalline oxysilaboranes due to intericosahedral constructive x-ray interference between parallel faces of corner artificial atoms 101. The icosahedral body centers of the nearest-neighbor corner artificial atoms 101 are randomly separated over a limited, finite range about 640 pm. A random separation of the corner artificial atoms 101 in the irregular borane hexahedra 300 of the picocrystalline oxysilaboranes results in a range of sharp x-ray diffraction peaks. The existence of a sharp x-ray diffraction peak for any fixed angle of incidence w is a characteristic of a long-range bond-orientational order in the picocrystalline oxysilaboranes due to self-aligned artificial atoms 101.

In order to appreciate the long-range bond-orientational order in the picocrystalline oxysilaboranes, it is purposeful to define the valence electrons of the hydrogen nuclei 103 as the valence electrons of the artificial atom 101 shown in FIG. 9. It therefore follows that the artificial atoms 101 of the picocrystalline oxysilaboranes are tetravalent atoms. More specifically, the valence electrons of the tetravalent artificial atoms 101 are oriented along a k(111) wave vector due to an intrinsic electric quadrupole moment.

The nucleus of carbon ¹²₆C is formed by a fusion of 12 nucleons (6 protons and 6 neutrons) by means of 36 quarks (18 up quarks and 18 down quarks). Nuclear fusion is accompanied by a very small decrease in the quantity of matter (mass) of the nucleons. The small decrease in mass is transformed into a resonant energy associated with ordered vibrations of the stable nucleus of carbon ¹²₆C. The atomic fusion of 12 boron nuclei 102, by three-center chemical bonds of 36 valence electrons, likewise, results in the artificial atoms 101 of the picocrystalline oxysilaboranes. The atomic fusion of 12 boron nuclei 102 into the artificial atoms 101 intertwines rotational, vibrational and electronic degrees of freedom into rovibronic degrees of freedom supporting vibrations along k(111) wave vectors.

The novel utility of replacing natural carbon atoms by artificial atoms 101 in preferred picocrystalline oxysilaboranes pertains to the ability to establish the discrete quantization of energy levels in picocrystalline quantum dots in accordance with Dirac's relativistic wave equation. Although the electronic properties of graphene are known to be governed by Dirac's relativistic equation, graphene remains of limited use in electronic devices due to an absence of a band-gap energy. An extensive search for various other two-dimensional lattices comprised of strictly natural atoms has heretofore failed to remedy the limitations of graphene. The picocrystalline oxysilaboranes of the present invention can potentially provide a remedy of the limitations of graphene by replacing natural carbon atoms with artificial carbon atoms. Artificial atoms have a profound advantage in the sense that they can involve a relativistic quantization of energy levels.

By replacing some natural atoms with artificial carbon atoms 101 (in the form of boron icosahedra with a nearly-symmetrical nuclear configuration), an atomic engineering can be established. Atomic engineering can be supported by a chemical modification of artificial carbon atoms 101 that act as variable atomic elements in novel molecules supporting a picotechnology. Preferred types of pico-crystalline oxysilaboranes will be described by actual examples.

### Method of Making p-Type Picocrystalline Oxysilaborane

A method for making the oxysilaborane films of the present invention is a chemical vapor deposition causing the precipitation of a solid film by passing gas vapors containing boron, hydrogen, silicon, and oxygen over a heated substrate in a sealed chamber maintained at a pressure below that of the atmosphere. The preferred vapors are nitrous oxide N₂O and the lower-order hydrides of boron and silicon, with diborane B2H6 and monosilane SiH₄ being the most preferred. Both hydrides can be diluted in a hydrogen carrier gas. By passing hydrogen-diluted di-borane and monosilane, and optionally nitrous oxide, over a sample heated above −200° C. at a pressure of −1-30 torr, a solid oxysilaborane film self-assembles over the substrate in a picocrystalline borane solid under preferred conditions.

The heating can be realized with equipment generally known to those skilled in the art of semiconductor processing. A molybdenum susceptor, by way of example, can provide a solid substrate carrier that can be resistively or inductively heated. The substrate can be heated without any susceptor in a resistively-heated quartz tube. In all these methods there can exist heated surfaces (other than the intended deposition substratum) on which an oxysilaborane film is deposited. The substrate can be heated without a susceptor in a cold-wall reactor by radiative heat by halogen lamps in a low-pressure rapid thermal chemical vapor deposition that minimizes reactor outgassing from heated surfaces coated by prior depositions. A preferred method for preparing the picocrystalline oxysilaboranes of the present invention is described after the processing in various examples is considered.

Whenever the deposition temperature exceeds −350° C. hydrogenation effects can be substantially eliminated. Conversely, by decreasing the deposition temperature below −350° C. a thin picocrystalline solid can become significantly hydrogenated, such that hydrogen can be actively incorporated in chemical bonds. The relative atomic concentration of hydrogen in a picocrystalline oxysilaborane solid deposited below −350° C. is usually within the range of 10-25% depending on the degree of oxygen incorporation. When hydrogen is not actively incorporated in the chemical bonds of a picocrystalline oxysilaborane solid, it is more specifically referred to as an oxysilaboride solid. An oxysilaborane solid substantially void of oxygen is more specifically referred to as a silaborane solid.

Oxygen can be incorporated into a picocrystalline oxysilaborane solid by either individual oxygen atoms or as part of water molecules. Any picocrystalline oxysilaborane solid that contains water molecules is said to be hydrous while a picocrystalline oxysilaborane solid comprised of individual hydrogen and oxygen atoms with a relatively negligible amount of water is said to be anhydrous. It has been observed that hydrous picocrystalline oxysilaborane solids tend to undergo a change in color and stoichiometry over time due, apparently, to the change in the trapped water. Unless explicitly stated otherwise, picocrystalline oxysilaborane solids in embodiments described hereinbelow are understood to be anhydrous. In order to minimize hydration, a deposition reactor is fitted with a load-lock chamber isolating the reaction chamber from the direct exposure to the ambient moisture. However, adsorbed moisture is difficult to fully eliminate during sample loading.

In addition to color changes, hydration can alter the boron-to-silicon ratio. In one preferred embodiment of oxysilaborane, the boron-to-silicon ratio is ideally six. An incorporation of atomic oxygen without hydration in oxysilaborane reduces the boron-to-silicon ratio while the incorporation of water molecules into hydrous oxysilaborane tends to increase the boron-to-silicon ratio. Both of these effects can exist concurrently. A preferred introduction of oxygen into anhydrous oxysilaborane is by means of nitrous oxide. The relative atomic concentration of boron in oxysilaborane amongst boron, silicon, and oxygen atoms is ideally −83%. In the absence of any hydration effects, the relative atomic concentration of boron amongst boron, silicon, and oxygen atoms does not significantly exceed −89%. The susceptibility to hydration depends, in part, on the relative oxygen atomic concentration in an oxysilaborane film and the method by which oxygen is introduced.

Self-assembled picocrystalline oxysilaborane has characteristics that are useful in electronic integrated circuits using covalent semiconductors, such as monocrystalline silicon. The electronic properties of an oxysilaborane solid can be modified in a controlled manner by processing conditions during wafer deposition. Picocrystalline oxysilaborane exhibits a long-range bond-orientational order. X-ray photoelectron spectroscopy (XPS) established the binding energy of the boron 1s electron in picocrystalline oxysilaborane as −188 eV, which is characteristic of chemical bonds in an icosahedral boron molecule. The oxygen 1s electron binding energy, −532 eV, is very similar to that of the oxygen 1s electron binding energy in a metallic oxide, which is different from that of the oxygen is electron in a glass.

The silicon 2p electron binding energy in the oxysilaborane solids of this invention exhibits a sharp energy peak of −99.6 eV over the full compositional range. This is important for several reasons. First of all, the absence of two energy peaks in oxysilaborane implies that the Si—Si and Si—B bonds possess an identical binding energy. Secondly, the measured binding energy of a silicon 2p electron in oxysilaborane is essentially that of monocrystalline silicon formed by tetrahedral chemical bonds in the diamond lattice. The silicon 2p electron binding energy in silicon dioxide is −103.2 eV. When oxysilaborane is deposited on amorphous silicon dioxide, there exists a distinct difference in the silicon 2p electron binding energy in the two compositions. The silicon 2p electron binding energy in oxysilaborane is that of monocrystalline silicon in a diamond lattice, despite being deposited over an amorphous oxide, due to the self-assembly of picocrystalline oxysilaboranes.

By suitably controlling the chemical vapor deposition processing conditions, picocrystalline oxysilaborane (B₁₂H₄)xSiyOz self-assembles in a preferred compositional range (2≦x≦4, 3≦y≦5, 0≦z≦2) bounded by picocrystalline silaborane p-(B₁₂H₄)₄Si₄ at one compositional extreme and by picocrystalline oxysilaborane p-(B₁₂²⁻H₄)₂Si₄O₂²⁺ at the other compositional extreme. The self-assembly of picocrystalline oxysilaborane (B₁₂H₄)xSiyOz in the preferred compositional range is due to reasons to be developed later hereinbelow. In order to better understand the preferred processing conditions, the processing of non-preferred species in the broader range (0≦w≦5, 2≦x≦4, 3≦y≦5, 0≦z≦3) of oxysilaborane (B₁₂)xSiyOzHw will be taught by a number of examples of a picocrystalline boron solid.

Now, various embodiments of oxysilaborane compositions according to the invention are described by examples, but the scope of the invention is not limited thereto. As will be understood by those skilled in the art, this invention may be embodied in other forms without a departure from the spirit or essential characteristics thereof. The disclosure and descriptions herein below are intended to be illustrative, but not limiting, of the scope of the invention. The first several examples teach a preferred processing of picocrystalline silaborane p-(B₁₂H₄)3Si₅ with the help of two examples in which processing of silaboride and oxysilaborane in a broader range (0≦w≦5, 2≦x≦4, 3≦y≦5, 0≦z≦3) of (B₁₂)xSiyOzHw is taught.

### Example 3

Phosphorous was diffused into the 100 mm diameter monocrystalline (001) p-type silicon substrate 404 with a resistivity of 15 Q-cm so as to result in an 8.7 ohm per square resistance, as measured by a four-point probe. The oxide was removed from the sample wafer by a hydrofluoric acid deglaze. The sample was inserted into a rapid thermal chemical vapor deposition (RTCVD) chamber of the type described by Gyurcsik et al. in “A Model for Rapid Thermal Processing,” IEEE Transactions on Semiconductor Manufacturing, Vol. 4, No. 1, 1991, p. 9. After loading the sample wafer onto a quartz ring, the RTCVD chamber was then closed and mechanically pumped down to a pressure of 10 mtorr. A 3% mixture, by volume, of diborane in hydrogen B₂H₆(3%)/H₂(97%) at a flow rate of 364 sccm and a 7% mixture, by volume, of monosilane in hydrogen SiH₄(7%)/H₂(93%) at a flow rate of 390 sccm were introduced into the evacuated RTCVD deposition chamber.

### Example 4

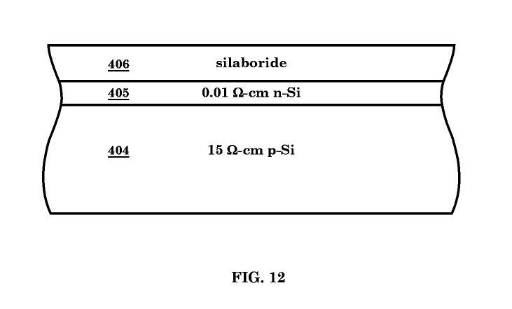

The reactant gas flow rate stabilized at a pressure of 3.29 torr, whereupon the tungsten-halogen lamps were turned on for 30 seconds and regulated so as to maintain the sample wafer at 605° C. As shown in FIG. 12, a thin silaboride solid 406 was deposited over the donor-doped region 405. The composition of the silaboride solid 406 was investigated by means of x-ray photoelectron spectroscopy (XPS). The binding energy of the boron 1s electron was measured as being 187.7 eV, which is consistent with icosahedral boron. The binding energy of the silicon 2p electron was measured to be 99.46 eV, which is characteristic of monocrystalline (001) n-type silicon. An XPS depth profile of the silaboride film 406 measured the relative atomic concentrations of boron and silicon within the silaboride solid 406 as being 86% and 14% respectively. Rutherford backscattering spectroscopy (RBS) measured the relative atomic concentrations of boron and silicon in the thin silaboride solid 406 as being 83.5% and 16.5% respectively.

The relative hydrogen concentration in the thin silaboride solid 406 was measured by way of hydrogen forward scattering (HFS) in which the hydrogen atoms are elastically scattered by incident high-energy helium atoms. Hydrogen forward scattering (HFS) is not as quantitative as the Rutherford backscattering spectroscopy (RBS), due to the oblique angle of incident helium atoms that causes a variation in the charge integration in various samples. Although the hydrogen counts per unit solid angle are constant, the solid angle itself can change between different samples. No hydrogen was detected. A solid comprised of boron and silicon in the absence of hydrogen is referred to as a silaboride composition.

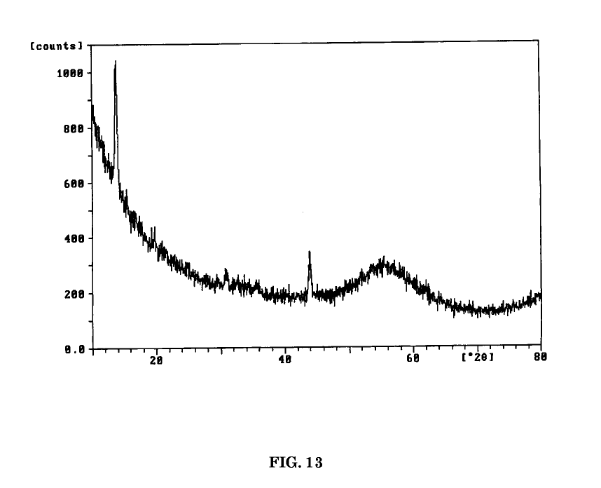

A secondary ion mass spectroscopy (SIMS) analysis established the ¹¹₅B/¹⁰₅B ratio of the silaboride solid 406 as the naturally-occurring ratio 4.03. The absence of any hydrogen or isotopic enrichment in the silaboride solid 406 of this example is due to the deposition temperature. A hydrogenation of silaborane can be realized when the deposition temperature is below ˜350° C. or when oxygen is introduced, as will be discussed in examples herein below. The silaboride solid 406 of this example was established by x-ray diffraction to be a picocrystalline boron solid. A GIXRD scan of the picocrystalline silaboride solid 406 of this example is shown in FIG. 13. The diffraction peak at 2θ=14.50° corresponds to the Bragg condition associated with the x-ray angle of incidence ω=7.25° of the GIXRD scan.

### Example 5

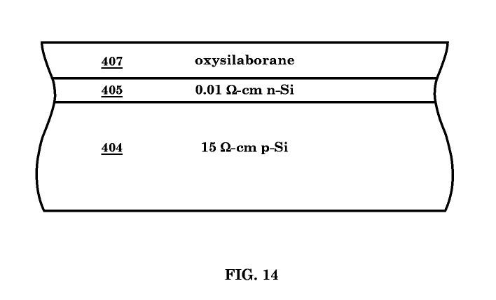

The procedure described above in Example 1 was carried out with the two exceptions that undiluted nitrous oxide N₂O was introduced at a flow rate of 704 sccm and the flow rates of the two hydride gases were doubled. A 3% mixture by volume of diborane in hydrogen B₂H₆(3%)/H₂(97%) at a flow rate of 728 sccm, a 7% mixture by volume of monosilane in hydrogen SiH₄(7%)/H₂(93%) at a flow rate of 780 sccm, and undiluted nitrous oxide N₂O at a flow rate of 704 sccm were introduced. The vapor flow rate was stabilized at 9.54 torr, whereupon the tungsten-halogen lamps were turned on for 30 seconds, and regulated, in order to maintain the sample substrate 404 at 605° C. As shown in FIG. 14, the oxysilaborane solid 407 was deposited upon the donor-doped region 405. The composition of the thin oxysilaborane solid 407 was evaluated by x-ray diffraction spectroscopy.

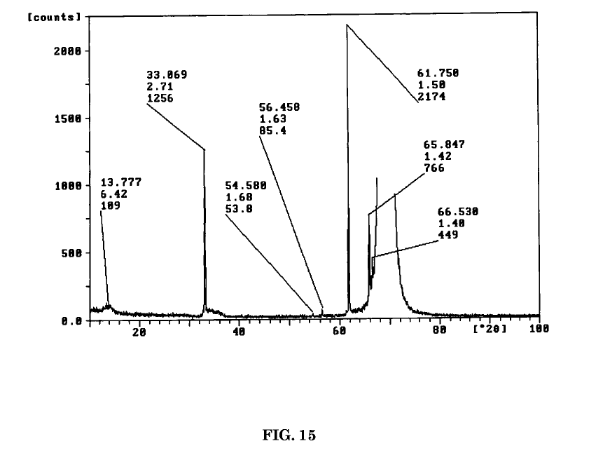

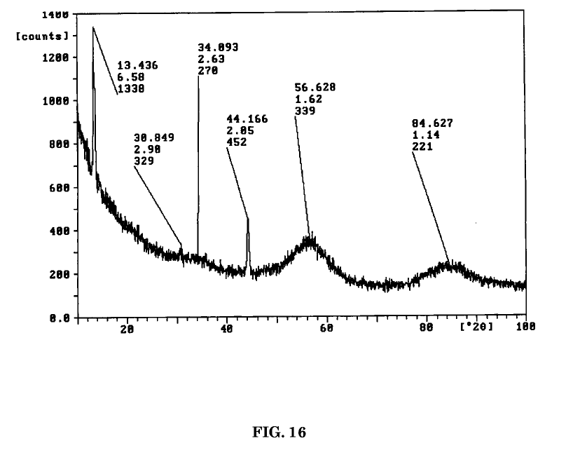

A conventional w-2θ XRD scan of the thin oxysilaborane solid 407 is shown in FIG. 15. The broadened diffraction peaks at 2θ=13.78° and 2θ=33.07° are characteristic of a picocrystalline boron glass. This is further corroborated by the GIXRD scan in FIG. 16, in which a diffraction peak at 2θ=13.43° corresponds to the Bragg condition associated with the x-ray angle of incidence w=6.70°. The composition of the oxysilaborane solid 407 was established by XPS spectroscopy. The binding energy of the boron 1s electron was 187.7 eV and the binding energy of the silicon 2p electron was 99.46 eV, which are the same as Example 1. The binding energy of the oxygen 1s electron was 524 eV. As measured by XPS, the relative bulk atomic concentrations of boron, silicon, and oxygen were 81%, 12%, and 7%.

By both Rutherford backscattering spectroscopy (RBS) and hydrogen forward scattering (HFS) the relative bulk atomic concentrations of boron, hydrogen, silicon, and oxygen within the oxysilaborane film 407 of this example were all respectively determined as being: 72%, 5.6%, 13.4%, and 9.0%. The picocrystalline boron solid 407 of the present example is not a borane solid but, rather, is much better characterized as an oxygen-rich composition (B12)₂Si_{3.5}O_{2.5}H in which the hydrogen atoms are, most likely, bonded to the oxygen atoms. Secondary ion mass spectroscopy (SIMS) established the isotopic ratio ¹¹5B/¹⁰5B as being the naturally-occurring ratio of the two boron isotopes, to within the experimental error. As will be soon established, the existence of a naturally-occurring isotopic ratio in ¹¹₅B/¹⁰₅B is indicative of the absence intertwined rovibronic energy levels that are capable of promoting the redistribution of electrons in response to microwave radiation.

### Example 6

The pyrolysis of boron and silicon hydrides was carried out by a low-pressure chemical vapor deposition (LPCVD) within a horizontal resistively-heated reactor comprising a five inch diameter quartz deposition tube, which was fixed on a table. The resistive heating element was mounted upon a motorized track, such that 75 mm silicon substrates could be loaded onto a quartz holder in the front of the tube at room temperature. Water vapor adsorbed onto the quartz walls during the sample loading provided a source of water vapor for the subsequent chemical reaction. A 75 mm diameter monocrystalline (001) n-type silicon substrate 408 of a resistivity of 20 Ω-cm was loaded onto a quartz holder in the quartz tube, which was sealed and mechanically pumped down to a base pressure of 30 mtorr.

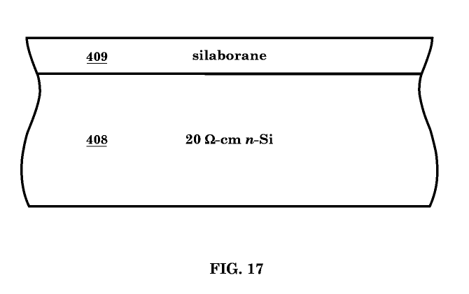

As shown in FIG. 17, a boron-rich film 409 was deposited on the (001) n-type silicon substrate 408 by introducing a 3% mixture, by volume, of diborane in hydrogen B₂H₆(3%)/H₂(97%) at the flow rate of 180 sccm and a 10% mixture, by volume, of monosilane in hydrogen SiH₄(10%)/H₂(90%) at a flow rate of 120 sccm. The gas flow rates stabilized at a deposition pressure of 360 mtorr. The motorized heating element was transferred over the sample. The deposition temperature was stabilized at 230° C. after a ˜20 minute temperature ramp due to the thermal mass of the quartz tube and the quartz sample holder. The pyrolysis was sustained for 8 minutes at 230° C., whereupon the motorized heating element was retracted and the reactive gases were secured. The relative atomic concentrations of boron and silicon in the silaborane film 409 were measured by different types of spectroscopy.

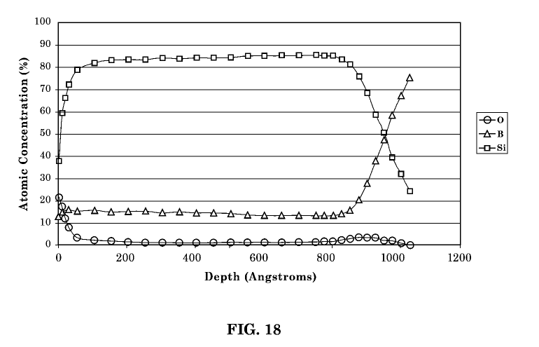

An x-ray photoelectron spectroscopy (XPS) depth profile of the silaborane film 409 was performed. The oxygen in the silaborane film 409 is due to an outgassing of water vapor from the quartz walls. FIG. 18 shows the relative atomic concentrations of boron, silicon and oxygen in the silaborane solid 409 as being respectively: 85%, 14%, and 1%. The binding energy of the boron is electron was 187 eV, which is characteristic of the bonds in icosahedral boron molecules. The XPS binding energy of the silicon 2p electron was 99.6 eV, which is characteristic of the silicon 2p electron in (001) monocrystalline silicon. The XPS binding energy of the oxygen 1s electron was measured as 532 eV. A depth analysis of the solid 409 by Rutherford backscattering spectroscopy (RBS) measured the relative bulk atomic concentrations of boron and silicon as 82.6% and 17.4% respectively.

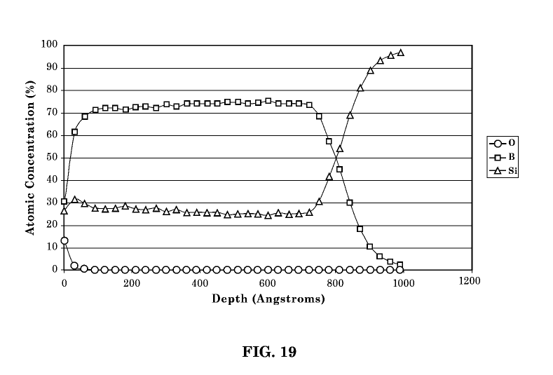

The Auger electron spectroscopy (AES) depth profile in FIG. 19 shows the relative atomic concentrations of boron, silicon, and oxygen in the silaborane solid 409 as being respectively: 73.9%, 26.1% and 0.1%. The thickness of the solid 409 was established by XPS, AES, and RBS as 998 Å, 826 Å, and 380 Å. The relative bulk atomic concentrations of boron, hydrogen and silicon were all established by RBS/HFS depth profiles of the silaborane solid 409 of this example as: 66.5%, 19.5%, and 14.0%. A secondary ion mass spectroscopy (SIMS) depth profile was carried out in order to establish the existence of any isotopic enrichment. An isotopic enrichment of boron ¹⁰₅B relative to boron ¹¹₅B was proven by the SIMS depth profile. Whereas the naturally-occurring ¹¹5B/¹⁰5B ratio is 4.03, the SIMS analysis measured the ¹¹₅B/¹⁰₅B ratio in the silaborane solid 409 as 3.81.

The film in Example 3 is referred to as a silaborane solid 409 since the small relative atomic concentration of oxygen is believed to be in the form of water. As a result, this film is better referred to as a hydrous silaborane solid 409. The conventional ω-20 XRD diffraction pattern in FIG. 6 and the GIXRD diffraction pattern in FIG. 8 were both obtained from the hydrous silaborane solid 409 in Example 3. As the result, the hydrous silaborane solid 409 is a nanocrystalline boron glass per the definition hereinabove. Although the conventional ω-2θ XRD diffraction pattern of the hydrous silaborane solid 409 in FIG. 6 is substantially that of the oxysilaborane solid 407 in FIG. 15, the picocrystalline boron solids are fundamentally distinguished by the isotopic enrichment of boron ¹⁰₅B relative to boron ¹¹₅B. This distinction impacts preferred embodiments of this invention.

One objective of the present invention is to establish a novel genus of self-assembled nanocrystalline oxysilaboranes promoting a redistribution of electrons amongst rovibronic energy levels in response to microwave radiation due to an uncompensated increase in entropy characterized by an isotopic enrichment of boron ¹⁰₅B relative to boron ¹¹₅B. The novelty and utility of such a redistribution of electrons by microwave radiation can be further appreciated by other examples.

### Hydrogen and Isotopic Enrichment

### Example 7

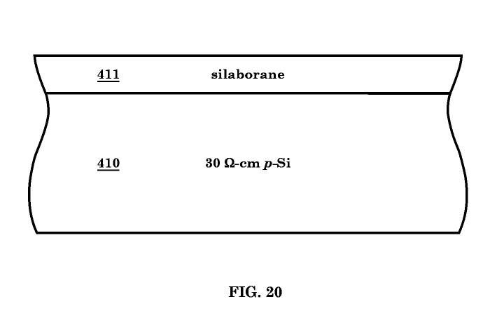

Referring to FIG. 20, a 100 mm diameter monocrystalline (001) p-type silicon substrate 410 with a resistivity of 30 Ω-cm was inserted onto a resistively-heated molybdenum susceptor in an EMCORE D-125 MOCVD reactor by a load-lock system that isolated the deposition chamber from the ambient. The chamber was pumped below 50 mtorr, whereupon a 3% mixture, by volume, of diborane in hydrogen B₂H₆(3%)/H₂(97%) at the flow rate of 360 sccm and a 2% mixture, by volume, of monosilane in hydrogen SiH₄(2%)/H₂(98%) at a flow rate of 1300 sccm were introduced into the chamber, after which the reactant gases were permitted to mix. Upon stabilization of the gas flow rate, the chamber pressure was regulated at 9 torr and the molybdenum susceptor was rotated at 1100 rpm.

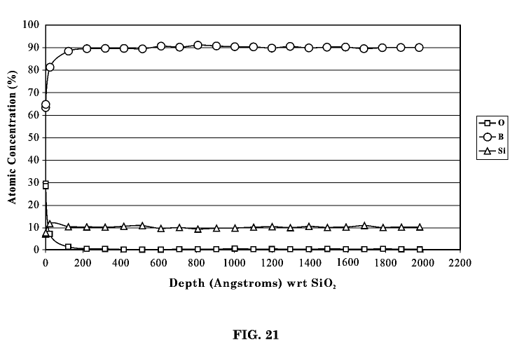

The substrate temperature was increased to 280° C. by the resistively-heated rotating susceptor. Upon the stabilization at the deposition temperature of 280° C., the chemical reaction was allowed to proceed for 5 minutes, whereupon the susceptor heating was arrested and the sample was allowed to cool to below 80° C. before removing it from the deposition chamber. A thin film 411 with a polymeric semitransparent color was deposited upon the substrate 410, as shown in FIG. 20. The silaborane solid 411 thickness was measured by variable-angle spectroscopic ellipsometry to be 166 nm. The silaborane solid 411 was smooth with no signs of a grain structure. The silaborane solid 411 did not exhibit visible hydration effects. The XPS depth profile in FIG. 21 measured the relative atomic concentrations of boron and silicon in the bulk solid 411 as being 89% and 10% respectively.

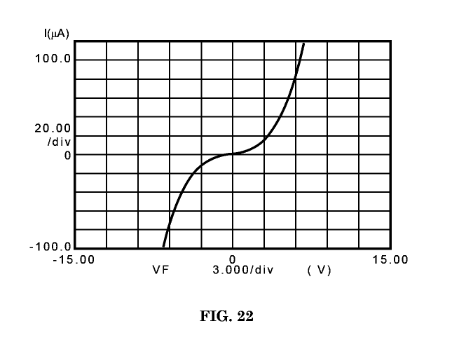

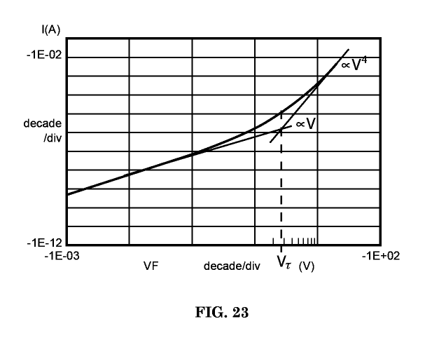

RBS and HFS analysis determined the relative atomic concentrations of boron, hydrogen, and silicon as being: 66%, 22%, and 11%. The silaborane solid 411 of this example is very similar to the silaborane solid 409 in Example 3 except that the silaborane solid 411 of this example did not exhibit measurable hydration effects. Electrical characteristics of the silaborane solid 411 were measured by an HP-4145 parameter analyzer, with sweep signals by a mercury probe. Linear and log-log graphs of the current-voltage characteristics of the silaborane solid 411 are shown in FIGS. 22-23. The nonlinear current-voltage characteristics of the sila-borane solid 411 are due to a space-charge-limited conduction current which deviates from Ohm's law beyond an onset of relaxation in accordance with FIG. 23.

Space-charge-limited current conduction in any solid was proposed by Mott and Gurney, Electronic Processes in Ionic Crystals, Oxford University Press, second edition, 1948, pp. 168-173. In analogy to Child's law of vacuum-tube devices, Mott and Gurney developed that a space-charge-limited current density J between electrodes, intervened by a solid dielectric, quadratically varies with an impressed electromotive force V, where d is the electrode separation, μ is the charge mobility, and E is the permittivity of the solid-state dielectric or semiconductor. The Mott-Gurney law is satisfied whenever a unipolar excess mobile charge exists due to a nonvanishing divergence of the electric field per Gauss' law. As will be developed, the space-charge-limited conduction current in the nanocrystalline oxysilaboranes is due to a charge conduction mechanism not heretofore known in the prior art.

### Example 8

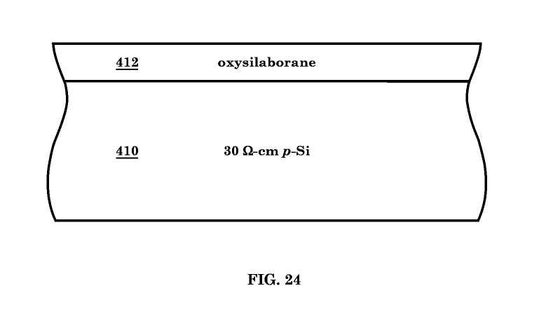

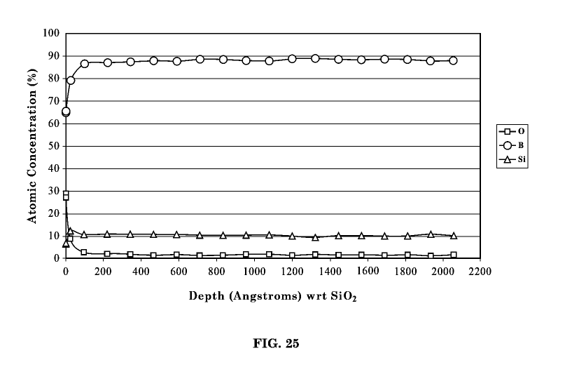

The procedure described in Example 4 was carried out with the sole exception that nitrous oxide was introduced at a flow rate of 40 sccm. As shown in FIG. 24, a thin oxysilaborane film 412 with a polymeric semitransparent color was deposited over the (001) monocrystalline p-type silicon substrate 410. The oxysilaborane film thickness was measured by variable-angle spectroscopic ellipsometry as being 159 nm. The XPS depth profile in FIG. 25 established the relative atomic concentrations of boron, silicon, and oxygen in the bulk oxysilaborane solid 412 as respectively being: 88.0%, 10.4%, and 1.6%. The inclusion of oxygen transformed the silaborane solid 411 in FIG. 20 of Example 4 into the oxysilaborane solid 412 in FIG. 24 of this example. The incorporation of oxygen altered the oxysilaborane solid 412 of this example relative to the silaborane solid 411 of Example 4.

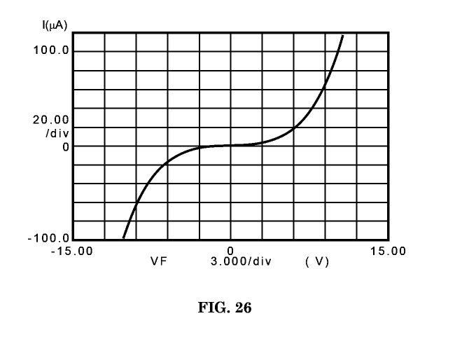

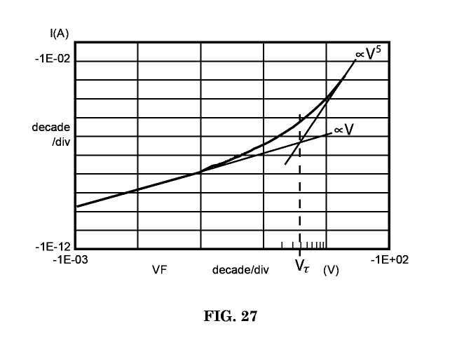

The electrical impedance of the oxysilaborane film 412 of the present example was measured by an HP-4145 parameter analyzer, with the sweep signals provided by a mercury probe. Linear and log-log graphs of the impedance characteristics of the oxysilaborane solid 412 of this example are respectively shown in FIGS. 26-27. The impedance of the oxysilaborane solid 412 of the present example increased relative to the silaborane solid 411 in Example 4. Whereas the space-charge-limited current in the silaborane solid 411 saturated at a quartic current-voltage characteristic, the space-charge-limited current in the oxysilaborane solid 412 of this present example saturated at a quintic current-voltage characteristic, as shown FIG. 27. The space-charge current is limited by mobile charge drift.

### Example 9

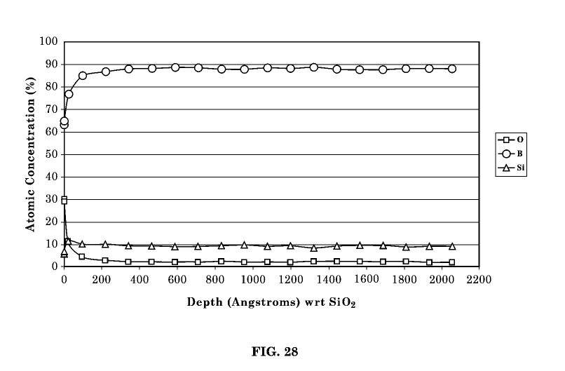

The procedure described in Example 5 was carried out with a single exception that the flow rate of the nitrous oxide was increased from 40 sccm to 80 sccm. The thickness of the oxysilaborane solid 412 of this example was measured by variable-angle spectroscopic ellipsometry as being 147 nm. The XPS depth profile in FIG. 28 established the relative atomic concentrations of boron, silicon, and oxygen in the bulk oxysilaborane solid 412 as respectively: 88.1%, 9.5%, and 2.5%. The relative atomic concentration of boron in the oxysilaborane solid 412 of this example is the same as the oxysilaborane solid 412 within Example 5. The atomic concentration of silicon in the oxysilaborane solid 412 of this example decreased relative to that of the oxysilaborane solid 412 in Example 5. The bulk atomic concentration of oxygen in the oxysilaborane solid 412 of this example was increased relative to that of the nanocrystalline oxysilaborane solid 412 in Example 5.

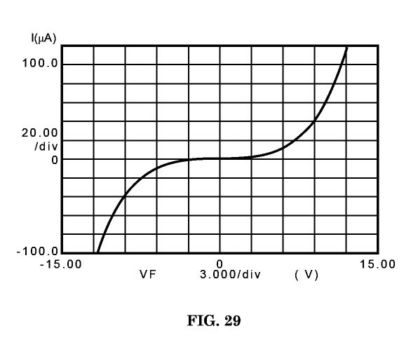

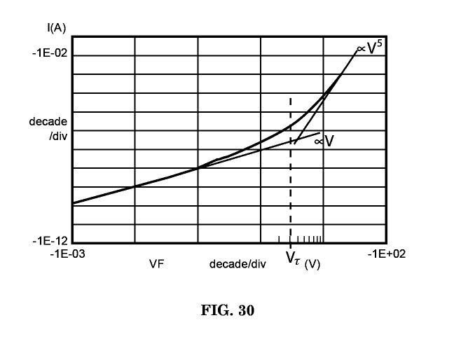

An RBS and HFS analysis measured the bulk relative atomic concentrations of boron, hydrogen, silicon, and oxygen as being: 63%, 23%, 11%, and 3%. The relative atomic concentration of oxygen is close to its RBS detection limit and, thus, is not accurate. The impedance of the oxysilaborane film of this example was measured by an HP-4145 parameter analyzer, with the sweep signals obtained by a mercury probe. Linear and logarithm graphs of the impedance characteristics of the oxysilaborane solid 412 are respectively shown in FIGS. 29-30. The impedance characteristics of the oxysilaborane solid 412 of this example exhibited a modestly greater impedance than that of the oxysilaborane solid 412 in Example 5.

### Example 10

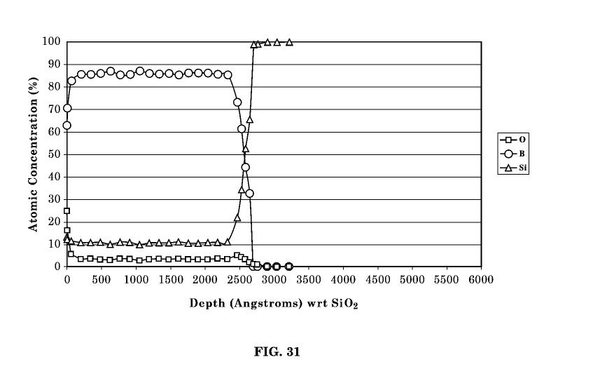

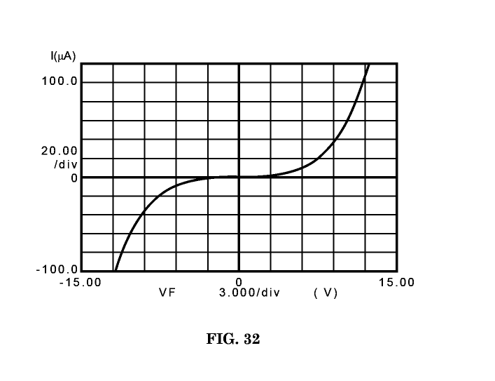

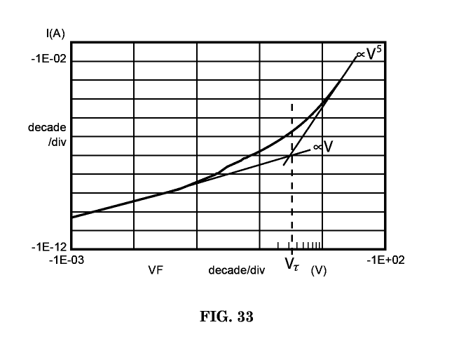

The procedure described in Example 6 was carried out with the sole exception that the flow rate of the nitrous oxide was increased from 80 sccm to 100 sccm. The thickness of the oxysilaborane solid 412 of this example was measured by variable-angle spectroscopic ellipsometry as 140 nm. The XPS depth profile in FIG. 31 measured the relative atomic concentrations of boron, silicon, and oxygen in the oxysilaborane solid 412 as being respectively: 85.9%, 10.7%, and 3.4%. The impedance of the oxysilaborane solid 412 of this example was measured by an HP-4145 analyzer, with the two sweep signals obtained by a mercury probe. Linear and log-log graphs of the current-voltage characteristics of the oxysilaborane solid 412 of this example are shown in FIGS. 32-33. The oxysilaborane solid 412 of this example exhibited a slightly higher impedance than that of Example 6.

### Example 11

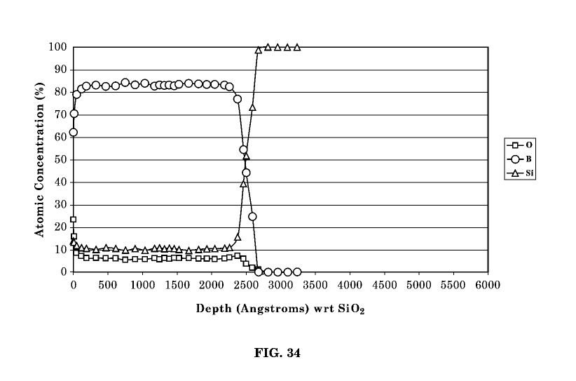

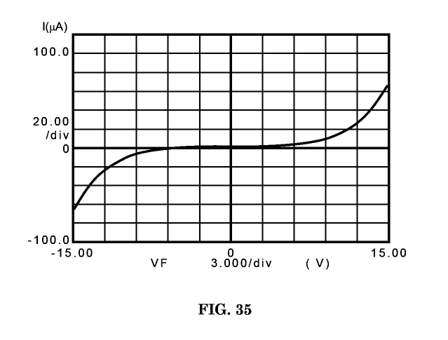

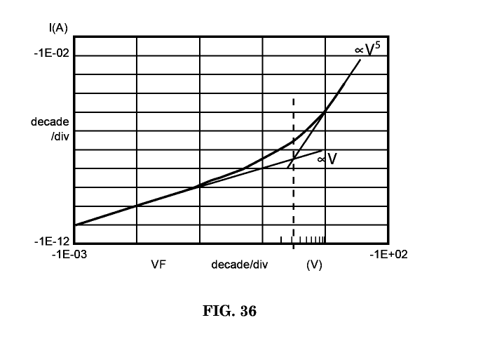

The procedure described in Example 7 was carried out with a sole exception that the flow rate of nitrous oxide was increased from 100 sccm to 300 sccm. The thickness of the thin oxysilaborane solid 412 of this example was measured by variable-angle spectroscopic ellipsometry as being 126 nm. The XPS depth profile in FIG. 34 measured the relative atomic concentrations of boron, silicon, and oxygen in the oxysilaborane solid 412 of this example as: 83.4%, 10.5%, and 6.2%. The impedance of the oxysilaborane solid 412 was measured by an HP-4145 parameter analyzer. The linear and log-log graphs of the impedance characteristics of the oxysilaborane solid 412 of this example are shown in FIGS. 35-36.

### Example 12

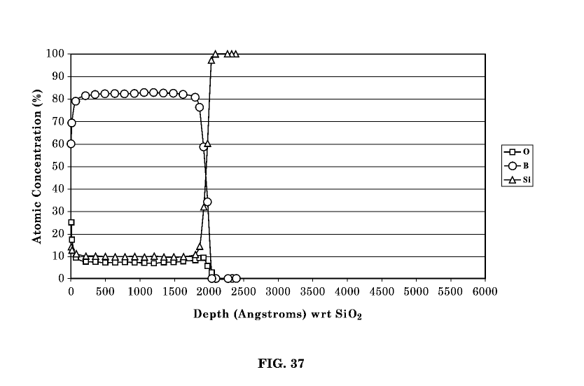

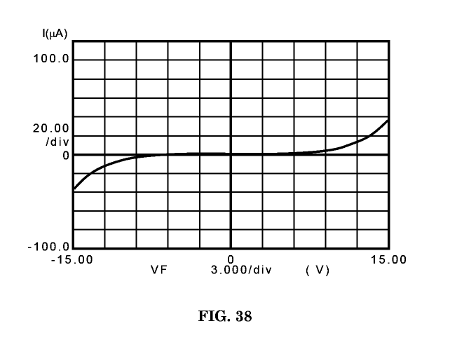

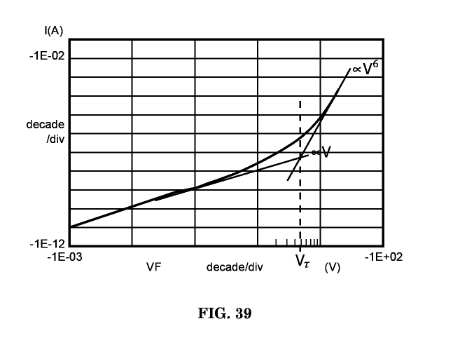

The procedure in Example 8 was carried out with the exception that the nitrous oxide flow rate was increased from 300 to 500 sccm. The thickness of the thin oxysilaborane solid 412 of this example was measured by variable-angle spectroscopic ellipsometry as 107 nm. The XPS depth profile in FIG. 37 established the relative atomic concentrations of boron, silicon and oxygen in the bulk oxysila-borane solid 412 of this example as being: 82.4%, 10.0%, and 7.6%. RBS and HFS analysis established the bulk relative atomic concentrations of boron, hydrogen, silicon, and oxygen: 66%, 20%, 9%, and 5%. The relative atomic concentration of oxygen is near its RBS detection limit. The impedance of the oxysilaborane solid 412 of this example was measured by an HP-4145 parameter analyzer, with sweep signals obtained by a mercury probe. Linear and log-log graphs of the impedance characteristics of the oxysilaborane solid 412 of this example are in FIGS. 38-39.

The oxysilaborane solid 412 of this example is oxygen-rich, such that it does not exist in the preferred compositional range (2≦x≦4, 3≦y≦5, 0≦z≦2) of nanocrystalline oxysilaborane (B₁₂H₄)xSiyOz but is contained in a broader compositional range (0≦w≦5, 2≦x≦4, 3≦y≦5, 0≦z≦3) of oxysilaborane (B₁₂)xSiyOzHw. It is significant that nanocrystalline oxysilaborane unpins the surface Fermi level of monocrystalline silicon so as to modulate the surface electrochemical potential of monocrystalline silicon and, at the same time, conducting electricity. In order to more fully appreciate this property, it is purposeful to consider examples in which an electrochemical rectifier is formed with monocrystalline silicon.

It is not possible in the prior art to vary the electrochemical potential of a monocrystalline silicon region throughout the forbidden energy region, while also conducting electric charge, due to an undesirable contact potential associated with mobile-charge diffusion between a monocrystalline silicon region and a conjoined material of a different work function. This deficiency is remedied by self-assembled nanocrystalline oxysilaborane by means of actual examples.

### Example 13

Monocrystalline silicon was epitaxially deposited over a (001) boron-doped p-type monocrystalline substrate 421 with a 100 mm diameter and 525 μm thickness. The resistivity of the degenerate monocrystalline silicon substrate 421 was 0.02 □-cm, which corresponds to an acceptor concentration of ˜4×10¹⁸ cm⁻³. A nondegenerate p-type monocrystalline silicon layer 422 was deposited on the silicon substrate 421. The epitaxial silicon layer 422 had a thickness of 15 μm and a resistivity of 2 Ω-cm, which corresponds to an acceptor impurity concentration of ˜7×10¹⁵ cm⁻³. All oxide was removed by a hydrofluoric acid deglaze. After the acid deglaze, the silicon substrate 421 was inserted onto a resistively-heated susceptor in an EMCORE MOCVD reactor by a load-lock system that isolated the deposition chamber from the ambient. The deposition chamber was pumped below 50 mtorr, whereupon a 3% mixture by volume of diborane in hydrogen B₂H₆(3%)/H₂(97%) at the flow rate of 150 sccm and a 2% mixture by volume of monosilane in hydrogen SiH₄(2%)/H₂(98%) at the flow rate of 300 sccm were introduced into the deposition chamber. Nitrous oxide N₂O was introduced at a flow rate of 100 sccm.

The gases were permitted to mix before entering into the deposition chamber. Upon the stabilization of the reactant gases, the chamber pressure was regulated at 1.5 torr while the susceptor was rotated at 1100 rpm. The substrate temperature was increased to 230° C. for 2 minutes. The susceptor temperature was yet further increased to 260° C., whereupon it stabilized and the chemical reaction was permitted to proceed for 12 minutes. The susceptor heating was secured and the sample was permitted to cool below 80° C. in the reactant gases before it was removed from the deposition chamber. An oxysilaborane film 423 was deposited. The thickness was measured by variable-angle spectroscopic ellipsometry as being 12.8 nm. Due to the thickness, the oxysilaborane film 423 showed no coloration.

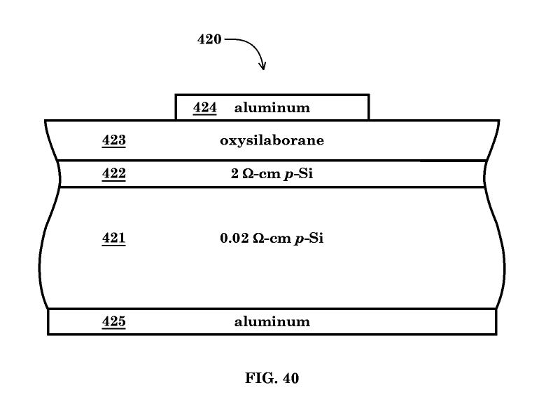

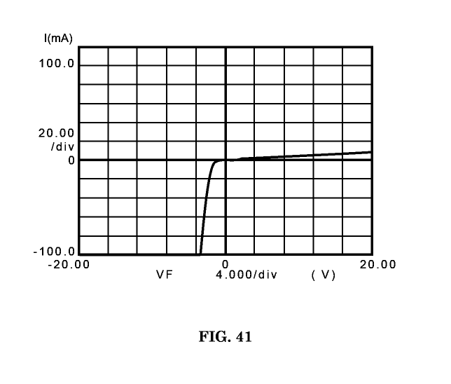

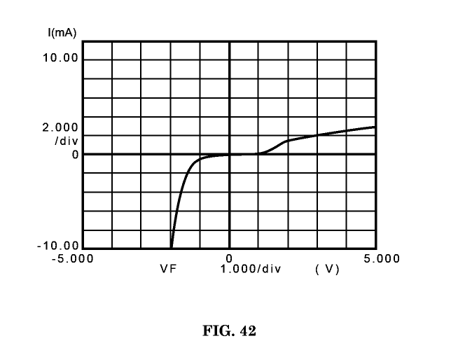

Aluminum was evaporated over the entire substrate 421 backside in a bell-jar evaporator, after which, a similar layer of aluminum was evaporated on the oxysilaborane film 423 through a shadow mask in the bell-jar evaporator. The topside aluminum formed the cathode electrode 424 and the backside aluminum formed the anode electrode 425, as shown in FIG. 40. The electrical characteristics of the p-isotype electrochemical rectifier 420 of this example were measured by an HP-4145 parameter analyzer, with the sweep signals obtained from the anode and cathode electrodes 425 and 424 by means of microprobes. Linear current-voltage characteristics of the p-isotype electrochemical rectifier 420 of this example are shown at two distinct current-voltage ranges in FIGS. 41-42. The electrochemical rectifier 420 achieves an asymmetrical electrical conductance without the aid of a p-n junction by means of a variation in the surface electrochemical potential.

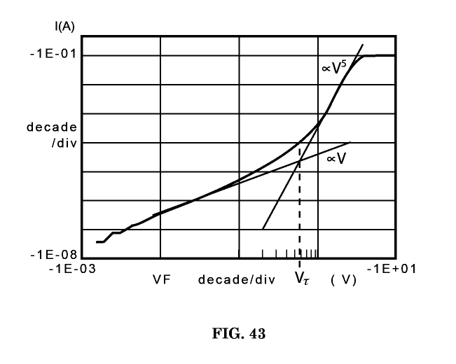

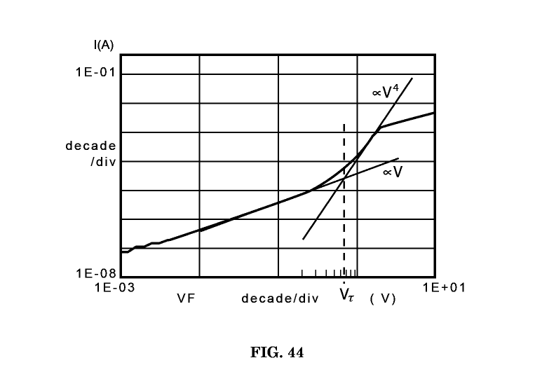

As shown in FIG. 41, a considerably greater current flows when the cathode electrode 424 is negatively-biased (forward-biased) relative to the anode electrode 425. When the cathode electrode 424 is positively-biased (reverse-biased) relative to the anode electrode 425, the much smaller current increases with an increased reverse bias beyond ˜1V. The increased reverse-bias current is believed to be due to deleterious interfacial effects due to non-ideal processing conditions. Forward-bias and reverse-bias logarithm current-voltage plots are represented in FIGS. 43-44. The asymmetrical current conduction is due to a built-in field.

### Example 14

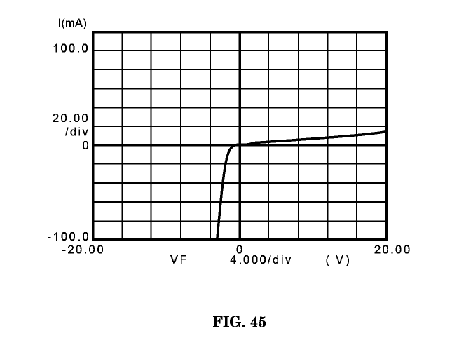

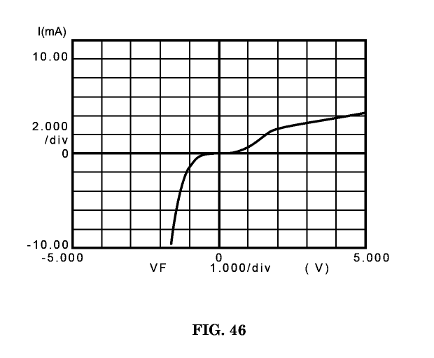

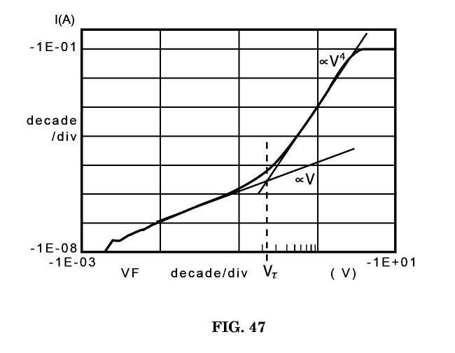

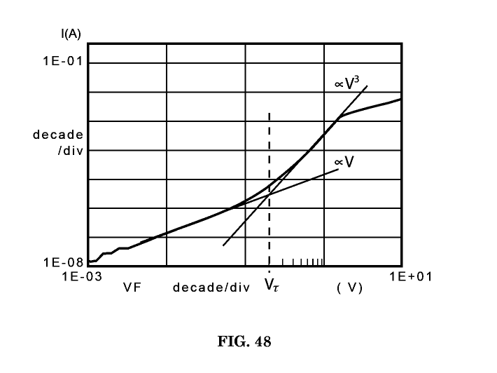

The procedure described in Example 10 was carried out with the sole exception that the flow rate of nitrous oxide N₂O was increased from 20 sccm to 65 sccm. The thickness of the oxysilaborane film 423 of this example was measured by variable-angle spectroscopic ellipsometry as 12.4 nm. The electrical characteristics of the p-isotype electrochemical rectifier 420 of this example were measured by an HP-4145 parameter analyzer, with sweep signals obtained from the anode and cathode electrodes 425 and 424 by means of microprobes. The linear current-voltage characteristics of the p-isotype electrochemical rectifier 420 of this present example are shown at two different ranges in FIGS. 45-46. Forward-bias and reverse-bias logarithm current-voltage plots are shown in FIGS. 47-48. Although the bulk composition of the oxysilaborane film 423 of this example is substantially that of prototypical oxysilaborane p-(B₁₂²⁻H₄)₂Si₄O₂²⁺, rectification does not appear to be ideal for reasons that will be discussed later herein below.

### Example 15

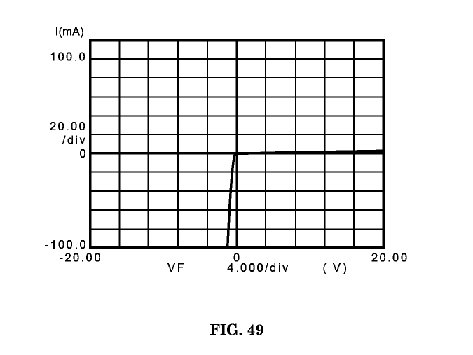

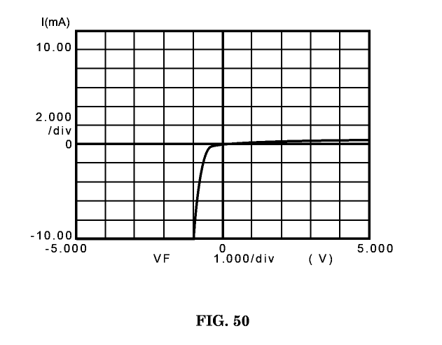

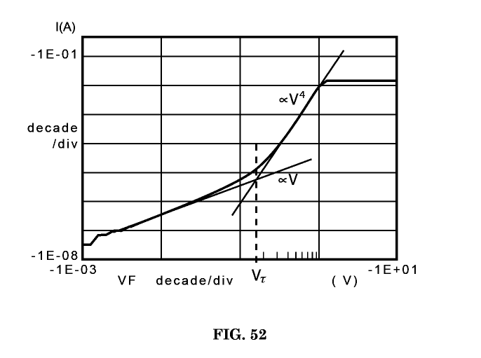

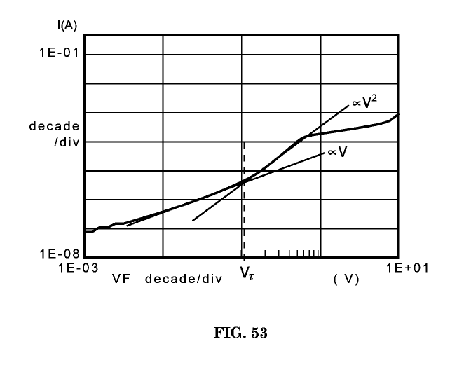

The procedure described above in Example 11 was carried out with the exception that the reaction time at 260° C. was decreased from 12 minutes to 6 minutes. The thickness of the oxysilaborane film 423 of this present example was measured by variable-angle spectroscopic ellipsometry as 7.8 nm. The electrical characteristics of the p-isotype electrochemical rectifier 420 of this example were measured by an HP-4145 parameter analyzer, with sweep signals obtained from the anode and cathode electrodes 425 and 424 by two microprobes. Linear current-voltage characteristics of the p-isotype electrochemical rectifier 420 of the present example are shown at three different current-voltage ranges in FIGS. 49-51. The forward-bias and reverse-bias logarithm current-voltage characteristics are presented in FIGS. 52-53. The rectification properties of this example are improved relative to Examples 10-11 due, in large part, to the thinner film 423.

### Example 16

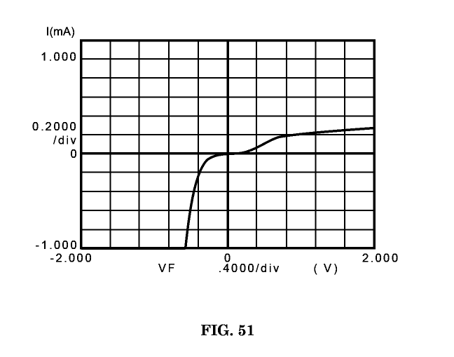

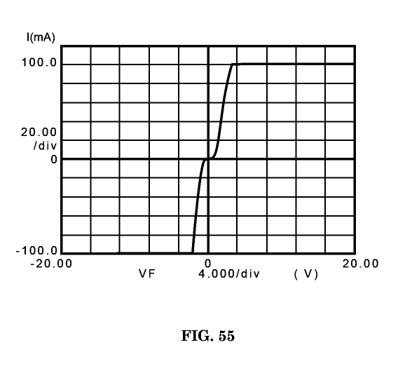

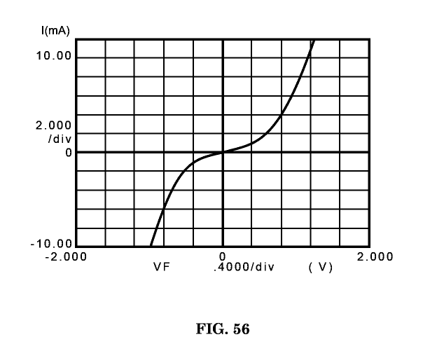

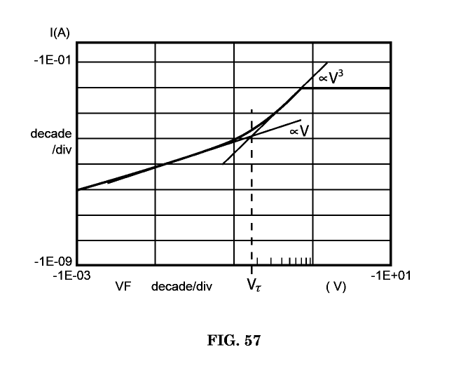

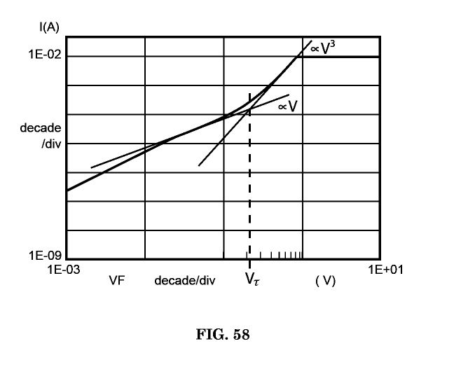

The procedure in Example 12 was carried out with the exception that nitrous oxide N₂O was never introduced. The thickness of the silaborane film 426 represented in FIG. 51 was measured by variable-angle spectroscopic ellipsometry as being 11.4 nm. The electrical characteristics of the device 420 were measured by an HP-4145 parameter analyzer, with the sweep signals obtained from the anode and cathode electrodes 425 and 424 by means of microprobes. The linear current-voltage characteristics of the device 420 are shown in FIGS. 55-56. The forward-bias and reverse-bias logarithm current-voltage plots are shown in FIGS. 57-58.

### Novel Electronic Properties of Oxysilaborane

Ignoring interfacial effects, the composition of the oxysilaborane film 423 Examples 11-12 is prototypical oxysilaborane p-(B₁₂²⁻H₄)₂Si₄O₂²⁺ and the silaborane film 426 Example 13 is silaborane p-(B₁₂H₄)₃Si₅. Oxysilaborane p-(B₁₂²⁻H₄)₂Si₄O₂²⁺ and silaborane p-(B₁₂H₄)₃Si₅ exhibit different, albeit complementary, electrochemical properties. The profound difference between them is exemplified by the fundamental difference in the rectification of the electrochemical devices 420 in Example 11 and Example 13 due to the critical role of oxygen. The difference in devices 420 of these examples is the oxygen concentration of the supramolecular films 423 and 426.

Referring to FIG. 41, the electrical current of the p-isotype electrochemical rectifier 420 in Example 11 increases significantly as the cathode electrode 424 is increasingly forward-biased (i.e. negatively-biased) relative to the anode electrode 425. As represented in FIG. 53, the forward-bias current in the p-isotype electrochemical rectifier 420 in Example 11 increases linearly with the bias voltage at a low current and increases with a quartic voltage dependence beyond the relaxation voltage. The forward-bias current-voltage characteristic of the p-isotype rectifier 420 in Example 11 is space-charge-limited by the oxysilaborane film 423 beyond a relaxation voltage, whereupon the transit time is less than the relaxation time.

A different situation occurs if the electrochemical rectifier 420 is reverse-biased. Referring to FIG. 41, the current of the p-isotype electrochemical rectifier 420 in Example 11 increases at a greatly reduced rate as the cathode electrode 424 is increasingly reverse-biased (i.e. positively-biased) relative to the anode electrode 425. This is attributed to the fact that the oxysilaborane film 423 in Example 11 is ideally prototypical oxysilaborane, p-(B₁₂²⁻H₄)₂Si₄O₂²⁺ which constitutes a solid in a closed-shell electronic configuration that supports a novel conduction current. The conduction current represented by the log-log graph in FIG. 44 is, in a number of ways, characteristic of a charge plasma injected in a semiconductor or dielectric. A good summary of this phenomenon is provided by Lampert and Mark in a book entitled Current Injection in Solids, Academic Press, 1970, pp. 250-275.

Whenever a charge plasma is injected into a semiconductor or dielectric, the current density and voltage vary linearly until a sufficiently high level of charge injection results in a space-charge-limited current density due to a breakdown in charge neutrality. High-level charge injection in a semiconductor tends to result in a quadratic dependence of a space-charge-limited current density on voltage while high-level charge injection in a dielectric tends to result in a cubic dependence of a space-charge-limited current density on voltage. The principal difference between a semiconductor and a dielectric is that the former is typically characterized by a large extrinsic mobile-charge concentration of a negative or positive polarity while the latter is typically characterized by a negligible mobile-charge concentration.

In principle, the log-log current-voltage characteristic of the electrochemical rectifier 420 in FIG. 44 should be characteristic of a charge plasma injected into a dielectric since the oxysilaborane film 423 in Example 11 has a bulk composition of prototypical oxysilaborane p-(B₁₂²⁻H₄)₂Si₄O₂²⁺ with an ideally closed-shell electronic configuration similar to that of a dielectric. As established by Lampert and Mark in the previous reference, mobile-charge diffusion tends to dominate the plasma-injected current-voltage characteristics of a dielectric in a diffusion length of either contact—such that the current density varies exponentially with voltage. If the dielectric length is much greater than the diffusion length, mobile-charge drift dominates the plasma-injected current-voltage characteristics—such that the current varies linearly with voltage up to a relaxation voltage V_{T}, whereupon it is space-charge-limited with a cubic variation in current density with voltage.

For example, per the above reference by Lampert and Mark, a silicon p-i-n diode with a length of the intrinsic silicon region of 4 mm exhibits a space-charge-limited current-voltage characteristic with a cubic dependency of the current density on the impressed voltage beyond a relaxation voltage of 10V. When the length of the intrinsic silicon region of the p-i-n diode was reduced to approximately 1 mm, the current density varied exponentially with an impressed voltage due to a dominance of mobile-charge diffusion. Referring, again, to FIG. 44, the electrochemical rectifier 420 in Example 12 possesses a drift space-charge-limited current-voltage characteristic in a thin oxysilaborane film 423 of only 12.4 nm, which has the bulk composition of oxysilaborane p-(B₁₂²⁻H₄)₂Si₄O₂²⁺.

This is only possible if the extrinsic charge concentration is sufficiently large that the Debye length of the oxysilaborane film 423 is less than approximately 4 nm. The extrinsic charge concentration of self-assembled oxysilaborane p-(B₁₂H₄)ₓSi_{y}O_{z} over the compositional range (2≦x≦3, 4≦y≦5, 0≦z≦2) is ideally constant at p₀≈10¹⁸ cm⁻³ due to the nuclear electric quadrupole moment of the all-boron fullerenes. The extrinsic concentration p₀, thus corresponds to the impurity doping concentration in monocrystalline silicon at the onset of bandgap narrowing. Prototypical oxysilaborane is a very novel compound, since it exhibits a closed-shell electronic configuration and an extrinsic mobile-charge concentration near the onset of bandgap narrowing in silicon.

As noted above, although it does not exhibit a long-range periodic translational order that is detectable by x-ray diffraction, self-assembled diamond-like oxy-silaborane p-(B₁₂²⁻H₄)₂Si₄O₂²⁺ possesses a long-range bond-orientational order that is compatible with monocrystalline silicon. This long-range bond-orientational order results in a charge conduction mechanism in self-assembled diamond-like oxysilaborane which is complementary to that of mono-crystalline silicon. The charge conduction in monocrystalline silicon is due to the itinerant displacement of mobile electrons in an extended conduction energy band and the itinerant displacement of mobile holes within an extended valence energy band—with both extended energy bands separated by a forbidden energy region.

### Example 17

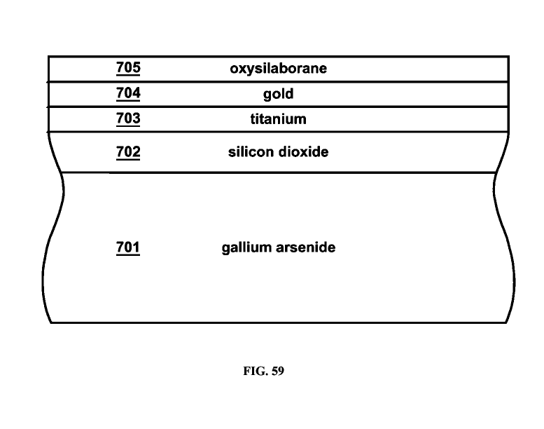

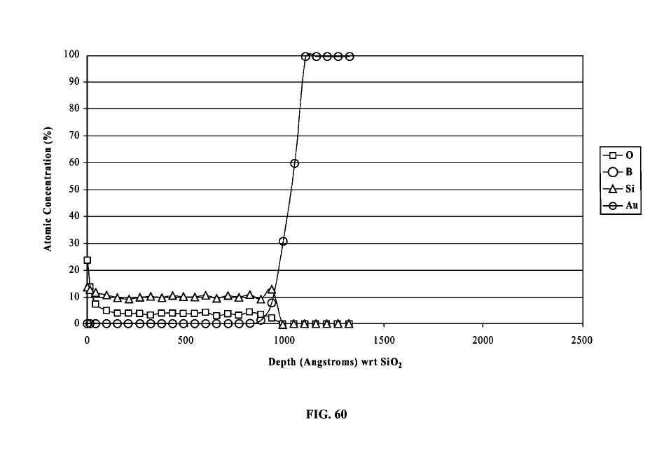

Referring to FIG. 59, a silicon dioxide film 702 was deposited over a gallium arsenide substrate 701. A titanium film 703 and a gold film 704 were evaporated over the silicon dioxide film 702. The substrate 701 was loaded onto a resistively-heated susceptor in a D-125 MOCVD chamber. The chamber was then mechanically pumped below 50 mtorr, whereupon a 3% mixture by volume of diborane in hydrogen B₂H₆(3%)/H₂(97%) at a flow rate of 360 sccm and a 2% mixture by volume of monosilane in hydrogen SiH₄(2%)/H₂(98%) at a flow rate of 1300 sccm were introduced into the chamber. At the same time, undiluted nitrous oxide N₂O was introduced at a flow rate of 150 sccm. The gases were allowed to mix and to stabilize before entering the deposition chamber of the MOCVD reactor. Upon stabilization of the reactant gas flow rate, the chamber pressure was regulated at 20 torr and the molybdenum susceptor was rotated at 1100 rpm. The substrate temperature was increased to 240° C. by the resistively-heated rotating susceptor. After stabilizing at the deposition temperature of 240° C., the chemical reaction was allowed to proceed for 20 minutes, whereupon the susceptor heating was halted and the sample was permitted to cool to below 80° C. prior to removing it from the deposition chamber. An oxysilaborane film 705 was deposited over the gold film 704, as shown in FIG. 59. The film thickness was measured by variable-angle spectroscopic ellipsometry to be 91.8 nm. The XPS depth profile in FIG. 60 established that the respective relative atomic concentrations of boron, silicon and oxygen in the oxysilaborane film 705 are: 85.2%, 10.0%, and 3.8%.

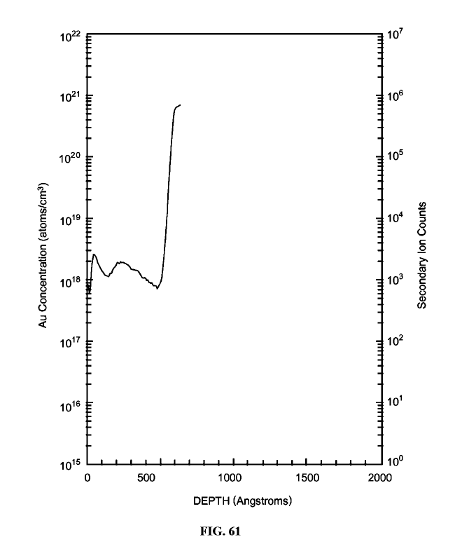

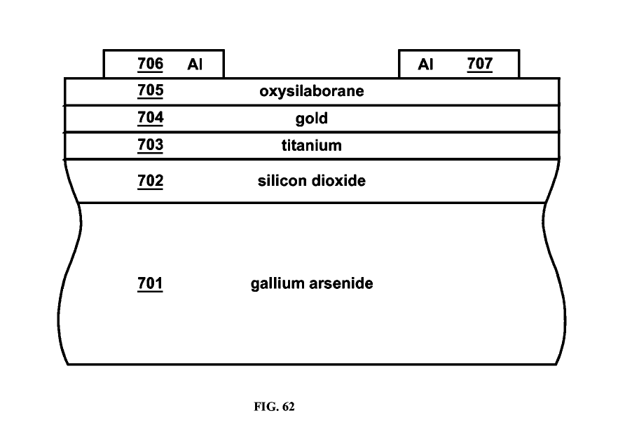

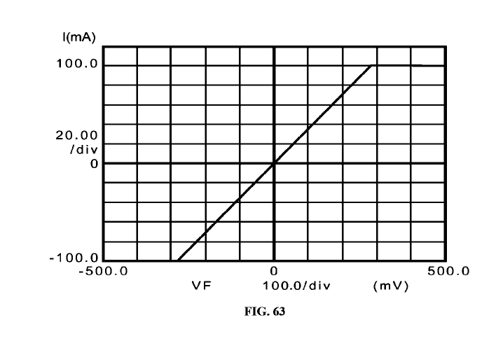

A secondary ion mass spectroscopy (SIMS) was then performed in order to measure a trace impurity concentration of gold in the oxysilaborane film 705. The SIMMS depth profile in FIG. 61 measured the gold atomic concentration as being ˜10¹⁸ cm⁻³. An RBS and HFS analysis measured the relative atomic concentrations of boron, hydrogen, silicon, and oxygen as respectively being: 70%, 17%, 10%, and 3%. Metal electrodes 706 and 707 were evaporated over the gold film, per FIG. 62, by evaporating aluminum through a shadow mask in a bell-jar evaporator. The current-voltage characteristic of the oxysilaborane film 705 was measured by an HP-4145 parameter analyzer, with the sweep signals obtained by two microprobes positioned on the metal electrodes 706 and 707. The graph of the current-voltage characteristics of the oxysilaborane film 705 is shown in FIG. 63. The current-voltage characteristics of the oxysilaborane film 705 exhibit an ohmic conduction current, with a 2.9Ω resistance due to the microprobe measurement apparatus. The incorporation of gold as a trace impurity alters the electrical properties of the oxysilaborane film 605 by eliminating space-charge effects. The incorporation of gold impurities in oxysilaborane can be achieved by including a gold precursor in the formation gas resulting in the deposition of an oxysilaborane film. Suitable gold precursors are volatile organometallic dimethylgold (III) complexes, with dimethylgold (III) acetate (CH₃)₂Au(OAc) being a preferred such gold precursor. The gold precursor can be introduced into the formation gas of oxysilaborane films by a hydrogen carrier gas in an MOCVD reactor. By incorporating trace gold impurities, the electrical conductance of supramolecular oxysilaborane can be substantially increased in a controlled manner.

It has been shown by the experiment above that by adjusting the chemical composition of oxysilaboranes electrical conduction properties change. It is believed that such adjustments control spin-orbit coupling and thereby the relaxation time τ can be varied in picocrystalline oxysilaborane, so as to result in novel and useful properties in a variety of device applications. It is further believed that by the incorporation of significant impurities such as gold, even at trace amounts, p-type oxysilaborane quantum mechanically transforms into an intrinsic silaborane (B₁₂H₄)₃Si₅ in which charge conduction is by means of massless Dirac fermions. This form of conduction is the conduction that has been identified in monolayer graphene. The advantages of such a conduction mechanism in picocrystalline oxysilaborane includes the fact that these novel compositions can be made into films and layers and combined with a variety of substrates, including monocrystalline silicon, to form electric devices currently unattainable with graphene.

Thus, one skilled in the art will recognize that layers of picocrystalline oxysilaboranes having varying amounts of oxygen and impurities such as gold can be deposited, for example by chemical vapor deposition techniques, to create electronic properties on a tailor made basis. One example would be to deposit a thin film of silaborane on aluminum, deposit a layer of oxysilaborane over it, deposit another layer of aluminum on top of the oxysilaborane and repeat that process. All devices, variations and adaptations for using the novel compositions of matter disclosed herein are intended to fall within the scope of the appended claims.

What is claimed is:

1. A solid compound consisting essentially of the chemical elements of boron, silicon, hydrogen and optionally oxygen wherein boron is present in a higher atomic concentration than the other elements as measured by XPS.

2. The compound of claim 1 having stoichiometric composition of: (B12Hw)xSiyOz wherein 3≦w≦5, 2≦x≦3, 2≦y≦5 and 0<z≦3.

3. The compound of claim 1 wherein w=4, x=2, y=5 and z=0.

4. The compound of claim 2 wherein w=4, x=2, y=4 and z=2.

5. The compound of claim 1 and further comprising a trace significant impurity of a coinage metal.

6. The compound of claim 1 and further comprising a trace significant impurity of gold.

7. The compound of claims 1-6 wherein the atomic concentration of boron is from about 63% to about 89% as measured by XPS.

8. A solid compound having stoichiometric composition of: (B12Hw)xSiyOz wherein 3≦w≦5, 2≦x≦3, 2≦y≦5 and 0<z≦3.

9. The compound of claim 8 wherein w=4, x=2, y=5 and z=0.

10. The compound of claim 8 wherein w=4, x=2, y=4 and z=2.

11. The compound of claim 8 wherein the atomic concentration of boron is from about 63% to about 89% as measured by XPS.

12. A composition of matter wherein the compound of claim 8 is formed on a substrate comprising monocrystalline silicon.

13. A solid compound formed by chemical vapor deposition consisting essentially of boron, silicon, oxygen and hydrogen.

14. The compound of claim 13 wherein boron is present in a higher atomic concentration than the other elements as measured by XPS.

15. The compound of claim 13 wherein said chemical deposition is performed on a substrate.

16. The compound of claim 13 wherein said chemical vapor deposition is performed at temperatures of from about 200 to about 350 degrees C. and pressures from about 1 to about 30 torr.

17. The compound of claim 13 wherein said chemical deposition is performed on a substrate.

18. The compound of claim 17 wherein said substrate is monocrystalline silicon.

19. A solid compound formed by self-assembly comprising boron and silicon wherein boron is present in a higher atomic concentration than the other elements as measured by XPS.

20. The compound of claim 19 wherein said boron is present is substantially icosahedron form.

21. The compound of claim 19 and further comprising a trace significant impurity of gold.

22. The compound of claim 19 self-assembled on a substrate comprising crystalline silicon.

23. A product formed by the process of:
a) heating a substrate to a temperature of from about 200 to about 350 degrees C. in a vacuum chamber,
b) introducing into said chamber gases comprising the elements of boron, hydrogen, and silicon; and
c) forming a film on said substrate from such gases.

24. The product of claim 23 wherein said vacuum chamber is maintained at a pressure between about 1 torr and about 30 torr.

25. The product of claim 23 wherein said temperature is kept below about 300 degrees C.

26. The product formed by the process of claim 23 wherein the process comprises the additional use of a gas comprising gold.

27. The product formed by the process of claim 26 wherein said gold is introduced via a mixture of hydrogen and dimethylgold (III) acetate ((CH3)2 Au(OAc)).

28. The product formed by the process of claim 23 using a metal organic chemical vapor deposition chamber.

29. The product formed by the process of claim 23 using a rapid-thermal chemical deposition chamber.

30. The product formed by the process of claim 23 wherein said gases are selected from the group consisting of nitrous oxide (N2O), diborane (B2H6), monosilane (SiH4) water (H2O) and hydrogen gas (H2).

31. The product formed by the process of claim 23 wherein the resulting film has a relative boron atomic concentration of about 80% as measured by XPS.

32. The product formed by the process of claim 23 wherein said substrate comprises monocrystalline silicon.

33. A method of making a composition of matter, comprising:
a) providing a substrate in an enclosed chamber;
b) controllably introducing into the chamber a gas mixture comprising hydrogen, boron and silicon;
c) heating the substrate to a temperature in the range of from about 200 to about 350 degrees C. to form a composition on said substrate, said composition having the formula:
(B12Hw)xSiyOz,
where: 3≦w≦5, 2≦x≦3, 2≦y≦5 and 0<z≦3.

34. The method of claim 33 and further introducing a gas containing gold.

35. The method of claim 33 wherein said substrate is silicon.

36. The method of claim 33 and further comprising the step of minimizing hydration by isolating the enclosed chamber from ambient moisture.

37. The method of claim 33 wherein said composition is formed as an epitaxial layer on said substrate.

38. A method for forming a boron based composition with oxygen enriched regions comprising:
a) providing a substrate in an enclosed chamber;
b) heating the substrate to temperatures in the range of from about 200 to about 350° C.;
c) controllably introducing into the chamber a gas mixture comprising hydrogen, boron silicon and optionally oxygen;
d) controllably varying the oxygen gas introduction over time to form a composition having regions substantially devoid of oxygen and regions with oxygen content.

39. The method of claim 38 wherein the boron based composition has regions with and without oxygen all within the range of the formula:
a) (B12Hw)xSiyOz, wherein: 3≦w≦5, 2≦x≦3, 2≦y≦5 and 0<z≦3.

40. The method of claim 39 wherein the composition is formed as a layered film comprising a first layer substantially devoid of oxygen and a second layer with oxygen content.

41. A solid compound comprising boron as the majority chemical element, hydrogen as a minority chemical element, and having:
a) no sharp x-ray diffraction peak for a diffraction angle 2θ when said compound is subjected to w-2θ x-ray diffraction, wherein the x-ray angle of incidence w is maintained at half of the diffraction angle 2θ, which is varied over 7°≦2θ≦80°; and
b) one broad x-ray diffraction peak within the range of diffraction angles 32°<2θ<36° when said compound is subjected to w-2θ x-ray diffraction, wherein the x-ray angle of incidence w is maintained at half of the diffraction angle 2θ, which is varied over 7°≦2θ≦80°.
c) one broad x-ray diffraction peak at a diffraction angle 2θ contained in 12°<2θ<16° when said compound is subjected to w-2θ x-ray diffraction, wherein the x-ray angle of incidence w is maintained at half of the diffraction angle 2θ, which is varied over 7°≦2θ≦80°; and
d) a sharp x-ray diffraction peak for a fixed x-ray angle of incidence w that corresponds to half of a diffraction angle 2θ in the range 12°<2θ<16° when said compound is subjected to grazing-incidence x-ray diffraction, wherein the x-ray angle of incidence is fixed at an angle w≦8° and the diffraction angle is varied over the range 7°≦2θ≦80°.

42. The compound of claim 41 specifically having stoichiometric composition of (B12Hw)xSiyOz with 0<w≦5, 2≦x≦4, 2≦y≦5 and 0≦z≦3.

43. The compound of claim 41 wherein an isotopic enrichment exists such that the ratio of boron 115B to boron 105B is lower than the naturally-occurring ratio.
